(19) United States
(12) Patent Application Publication
(10) Pub. No.: US 2026/0337761 A1
(43) Pub. Date: Oct. 29, 2026

(54) DIAMOND, DIAMOND-METAL COMPOSITE, AND OTHER STRUCTURED MATERIALS, SYSTEMS, AND METHODS

(71) Applicant: JUPITER VOLTA INC., BERKELEY, CA (US)

(72) Inventors: JEREMY SCHOLZ, BERKELEY, CA (US); MATTHEW ROBINSON, ORINDA, CA (US); AVIV ZOHMAN, BERKELEY, CA (US); ALEXANDER SHERMAN, BERKELEY, CA (US)

(21) Appl. No.: 19/657,825

(22) Filed: Apr. 24, 2026

Related U.S. Application Data
(60) Provisional application No. 63/793,881, filed on Apr. 24, 2025.

(51) Int. Cl. C23C 16/27; C23C 16/458; C23C 16/505

(52) U.S. Cl. CPC C23C 16/272; C23C 16/4584; C23C 16/505

(57) ABSTRACT

A system is provided. The system includes a plasma chamber coupled to an RF generator, wherein a plasma formed in the plasma chamber is densified using an RF field generated by the RF generator, and an axial force generated by current from the Z-pinch electrode. The system includes a reactant inlet into the plasma chamber, wherein one or more reactant species are converted into active species in the plasma, and an outlet from the plasma chamber, through which the active species leave the plasma chamber. A substrate is positioned adjacent to the outlet such that the active species form a material on the substrate.

### CROSS REFERENCE TO RELATED APPLICATIONS

This application is a non-provisional application for patent entitled to a filing date and claiming the benefit of earlier-filed U.S. Provisional Patent Application Ser. No. 63/793,881, filed Apr. 24, 2025, which is hereby incorporated herein by reference in its entirety.

### BACKGROUND

Conventional solutions for depositing metals and CVD films have drawbacks. For example, CVD films of limited types of materials can be formed using a direct current (DC) plasma arc, although these systems can produce a directed local area plasma. Microwave deposited CVD films can have good quality, but the deposition rates can be slower, and the deposition cannot be localized to an area or directed to deposit on certain areas of a substrate (e.g., to be useful in an additive manufacturing system). CVD can be done in one system, and then parts moved to another system for metal deposition, but this requires exposure to air and cooldown between processes, which limits product quality.

### BRIEF DESCRIPTION OF THE DRAWINGS

FIG. 1A illustrates components of a stabilized plasma system (e.g., a Z-pinch plasma system, or a vortex stabilized plasma system) according to aspects of the present disclosure

FIG. 1B shows a schematic of an example of an RF stabilized plasma system, in accordance with some embodiments.

FIG. 1C shows another schematic of an example of an RF stabilized plasma system, in accordance with some embodiments.

FIG. 2 illustrates an example of an alternative system configuration where tangential gas injectors cause a vortex flow pattern within the chamber in accordance with some embodiments.

FIG. 3A depicts a reactor in the form of an RF resonator, providing RF power to a pinch zone prior to the pinch in accordance with some embodiments.

FIG. 3B illustrates the RF wave acting exclusively on the outside of the pinch cylinder, the area of trouble with respect to cooling by neutrals and formation of mean residence time (MRT) nucleation sites, without interfering with the denser core of the pinch where the fusion is happening in accordance with some embodiments.

FIGS. 3C and 3D depict reactors configured to take part in plasma driven reactions according to aspects of the present disclosure.

FIGS. 3E and 3F show positions of additional liquid or solid materials inputs according to aspects of the present disclosure.

FIG. 3G shows a schematic of an example of an atmospheric isolation device containing a plasma column in accordance with some embodiments.

FIG. 4 shows some examples of materials and applications of the materials that can be produced using the systems and methods described herein.

FIG. 5 shows an experimental image of a dense column of plasma (e.g., plasma column in FIGS. 1B and 1C) formed using the systems and methods described herein.

FIG. 6 shows a schematic diagram of an example of a radially additive diamond (RAD) printer system that can enable the extreme plasma temperatures needed for rapid diamond growth in accordance with some embodiments.

FIG. 7 illustrates a material growth stage assembly configured for radial or otherwise directed additive deposition in accordance with some embodiments.

FIG. 8 builds on the architecture of FIG. 7 by emphasizing the interaction between the stabilized plasma jet and a rotating substrate oriented at a controlled angle relative to the jet axis in accordance with some embodiments.

FIG. 9 introduces a more flexible deposition configuration in which the plasma generation device itself is mounted on a multi-axis articulating arm in accordance with some embodiments.

FIG. 10 further generalizes the system into a full additive manufacturing platform in which both the plasma source and the substrate platform can move in multiple axes in accordance with some embodiments.

### DETAILED DESCRIPTION

Described herein are systems and methods for plasma confinement for fusion applications, and plasma confinement for chemical processes. The systems and methods described herein can solve the problem of chemical vapor deposition (CVD) growth being slow, expensive, and non-directed (e.g., occurring over a wide area). The systems and methods described herein can also enable the capability to move a CVD growth area around on a substrate, creating an additive patterned growth area.

In some cases, the systems and methods described herein can solve the problem of metal additive 3D printers being separated from CVD systems. Conventional CVD equipment does not enable the deposition of metal and CVD at the same time, so mixed materials of metal and CVD products cannot be created. In contrast, the systems and methods described herein can be used to form composite materials including a metal and a CVD material, such as metal particles surrounded by CVD metal, or layered stacks of alternating metal and CVD deposited films. The CVD deposited films can be carbon allotropes, nitrides, oxides, or other materials. Different CVD materials can be deposited using different CVD precursors, and optionally tuning the CVD growth parameters (e.g., plasma conditions, gas flow rates, and substrate temperature). By way of example, not by limitation, films can include titanium dioxide formed by a feed of titanium metal powder and oxygen gas with an argon carrier, or boron nitride formed by a feed of metallic boron powder and nitrogen gas, or tungsten carbide formed by a feed of tungsten metallic powder and methane gas, or gallium nitride formed by a mixture of vaporized metallic gallium, hydrogen, and nitrogen gas, or diamond formed using methane gas.

The systems and methods described herein also include an optional variable bias on the growth stage. A variable or tuned bias between the growth stage and the plasma, an electrode of the plasma CVD system, or ground potential, can be beneficial to solve the problem of CVD nucleation on a substrate and/or nucleation on a co-deposited metal film as part of a layered stack, or on a metal particle as part of a composite material.

The disclosed plasma-based systems and methods utilize various types of plasma sources, including radiofrequency (RF), microwave, and remote plasmas, along with gas flow control and/or RF energy to generate and confine plasmas (e.g., high-temperature or high-power) plasmas to small regions within an environmental isolation device (e.g., a vacuum or pressure chamber). The plasmas are then used to react gas, liquid, and/or solid reactants into desired chemical compounds. The resulting chemicals can be produced in a variety of forms, depending on the specific application and requirements. For example, gases may be formed through plasma decomposition of solids and/or liquids, while liquids or powders may be generated through plasma-induced reactions with gaseous reactants.

In some embodiments, the system for producing the products described herein is a stabilized plasma system. In some cases, the stabilized plasma system can include a Z-pinch current applied to the plasma, and in other examples, the Z-pinch current may be omitted. In some embodiments the plasma stabilization can be performed by vortex gas flow stabilization, and in other examples, vortex gas flow can be omitted. In some embodiments, the plasma can be stabilized by radially inward gas flow towards a radially central suction point. In some cases, the plasma can be stabilized by resonant RF standing wave structures.

A stabilized plasma system (e.g. a focused RF plasma system) according to aspects of the present disclosure solves the problem of power density limitation for plasma. The higher plasma power density of this system allows it to mitigate the negative effects of thermalization, recombination, and other inefficiencies. By concentrating a significant amount of energy into a fixed volume of plasma, the systems can drive chemical reactions at a much higher throughput. This high flow rate drastically reduces the residence time of reactants in the plasma, which is critical. A shorter residence time means the reactive species have less opportunity to either recombine into inert gas or lose their energy as waste heat. Higher power density solves the problem of throughput limitation for reactant gas (e.g., Nitrogen and Oxygen for synthesis of NO), in which reactants require a minimum plasma energization in order to react, but low power density prevents reaction energization from being achieved at high flow rates; high energy density allows high volumes of gas to be processed, improving throughput per system. A stabilized plasma system according to aspects of this invention solves the problem of generation of a high volumetric density of plasma species at high energy efficiency, such as generation of a high quantity of monatomic hydrogen and methyl radicals for CVD diamond growth, or Silyl radicals (SiH3*) for Silicon growth, or other neutral radicals for other types of CVD, or ionized metal species for PVD of metals. Some embodiment solutions for generating a stabilized plasma may solve RF application to high density plasma chemistry environments by inducing a current in the plasma instead of applying an electric field to the plasma, allowing for higher energy density, and allowing higher rates of plasma chemistry to occur. Other embodiments may generate dense stable plasma discharges by energization of a dense plasma via laser, or RF, or DC or AC current application. Further embodiments may generate species via pulsed application of current to create a Z-Pinch discharge, or via a nanosecond repetitive pulse (NRP) discharge, optionally at repetition frequencies of 10 Hz or higher, or 1000 Hz or higher, or 100,000 Hz or higher. In some embodiments, multiple methods may be combined, such as an RF inductive discharge combined with a Z-Pinch discharge. It should be appreciated that a stabilized plasma refers to a plasma in which spatial, temporal, or energetic instabilities are reduced, suppressed, or controlled such that the plasma maintains a desired geometry, density distribution, or temperature profile over a period of time sufficient for a defined process. Stabilization may be achieved through one or more mechanisms including, but not limited to, application of radiofrequency (RF) energy, induced or applied electrical currents, magnetic confinement forces including Z-pinch forces, gas flow shaping such as vortex or shear flow, pressure gradients, or combinations thereof. A stabilized plasma may include a continuous or quasi-continuous plasma column, jet, or region exhibiting reduced filamentation, reduced turbulence, or enhanced uniformity relative to an unstabilized plasma.

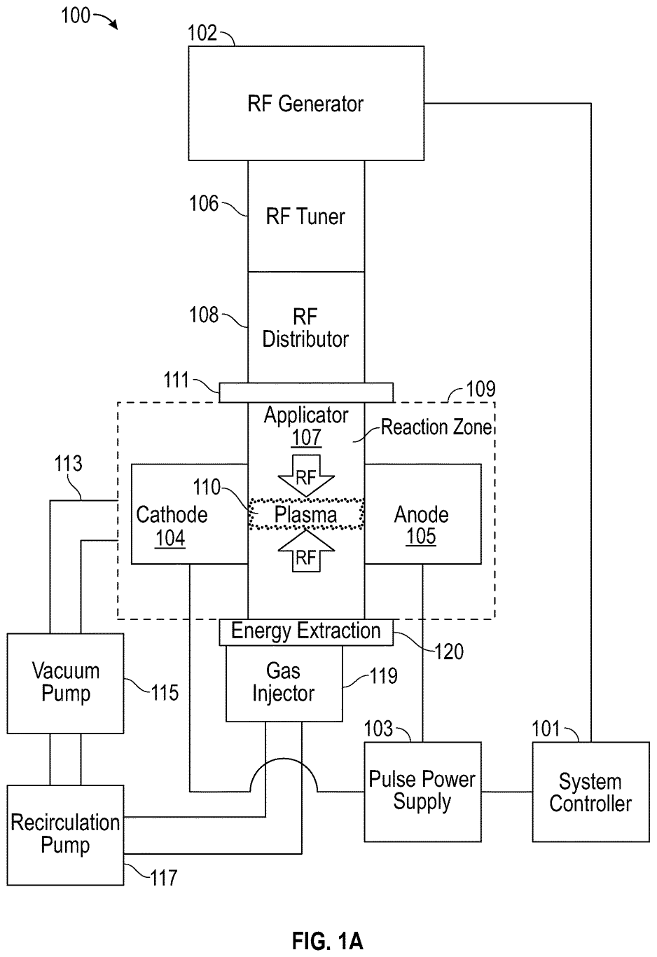

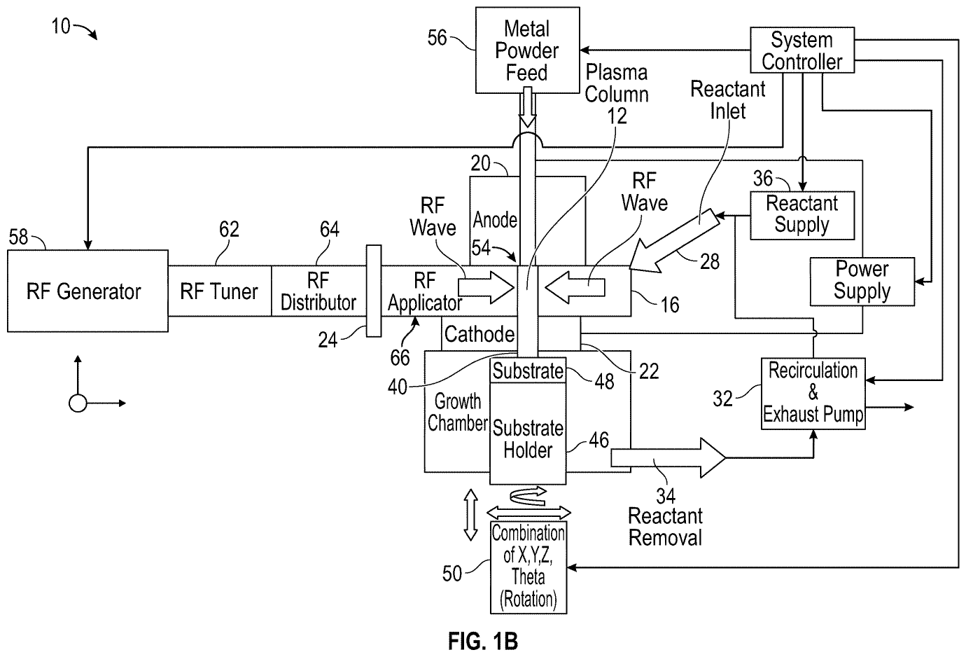

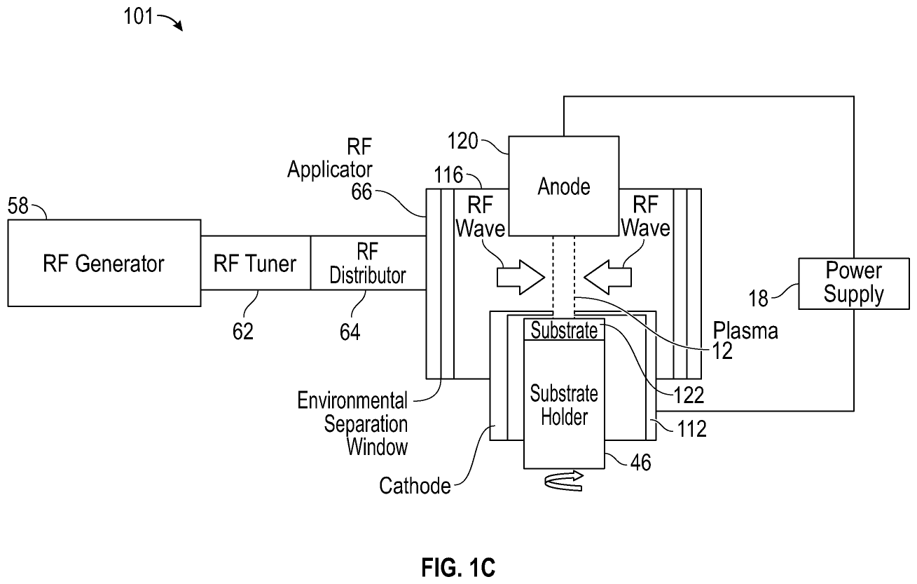

Shown in FIG. 1A, are components of a stabilized plasma system (e.g., a Z-pinch plasma system, or a vortex stabilized plasma system) 100 according to aspects of the present disclosure, which includes one or more RF generators 102, an RF tuner 106, one or more RF applicators 107, an RF distributor 108, and an atmospheric isolation device 109, such as a vacuum chamber or pressure vessel. In some implementations, a gas curtain may be used as the part or all of the atmospheric isolation device 109. An environmental separation window 111 may isolate the RF distributor from the environment inside the atmospheric isolation device 109. The term “chamber” is sometimes used herein as a convenient shorthand to refer to the atmospheric isolation device 109. The environmental separation window 111 permits RF radiation to enter the atmospheric isolation device 109, while isolating an environment inside it, e.g., the RF concentration zone 110, keeping fuel or reactant gas in and environmental effects out.

A reaction takes place within a reaction zone (RZ) inside the atmospheric isolation device 109. The location of the reaction zone is somewhat dependent on the nature of the reaction that takes place inside the chamber 109. For a volume process, the reaction zone is some sub-volume of the chamber volume for a volume process. In the example depicted in FIG. 1A, the reaction zone RZ is inside the RF applicator. For a surface process, the reaction zone refers to some surface within the chamber where the reaction takes place.

The stabilized plasma system 100 can optionally include a Z-Pinch drive device. In the implementation depicted in FIG. 1A, the Z-pinch drive device drives an AC or DC electric current through the initial RF pre-ionized plasma in an RF concentration zone 110 to cause all the ions in the plasma to compress. In this example, the RF concentration zone 110 may include or overlap with the reaction zone RZ. The Z-pinch drive device may include an AC or DC pulse power supply 103 having suitably configured capacitors and switches coupled to an anode 105, and cathode 104. The anode 105 acts as a positively charged terminal during operation, e.g., to supply a conventional current pulse to a plasma in the RF concentration zone 110, or to receive electrons from the plasma. During operation, the cathode 104 acts as a negatively charged terminal that supplies electrons to the plasma or receives conventional current from the plasma. The pulsed power supply 103 is configured to provide a driving pulse of electrical force of short duration between the cathode 104 and anode 105.

According to aspects of the present disclosure, the RF generator 102, tuner 106, distributor 108, applicator 107, window 111, and electrodes 104, 105 may be configured to pre-ionize a plasma prior to an optional Z-pinch for bulk chemical production. In some implementations, the electrodes, e.g., cathode 104 and anode 105, may be hollow in shape. The electrodes 104, 105 may be configured to distribute current uniformly on the plasma skin and prevent current from bunching on an electrode section causing damage. In some implementations, the RF ionization motivates a spreading of contact area with the electrodes 104, 105, reducing damage from high current density. The system 100 may optionally include an exhaust tube 113 coupled to a vacuum pump 115 that draws gas from within the atmospheric isolation device 109 to produce a vacuum therein. The system may further include a recirculation pump 117 and gas injector 119 configured to recirculate gas withdrawn from the atmospheric isolation device back into it. Fuel or reactant gas and other gases exit the chamber 109 through the exhaust tube 113 as a result of vacuum pull on the chamber from the vacuum pump 115. The recirculation pump 117 may compress gas for re-introduction to plasma in the chamber via a gas injector 119. The gas injector is generally a physical structure that directs gas flow, e.g., in jet form, into the plasma chamber 109. Such flow can be directed to interact with plasma in the RF concentration zone 110, creating vortex or shear flow stabilization. In a sheared flow stabilized plasma for nuclear fusion, a plasma column is compressed and heated by a strong electrical current. Plasma instabilities are suppressed by introducing a sheared plasma flow in which different parts of the plasma move at different speeds. The sheared flow effectively “smears” and breaks up the instabilities that would otherwise disrupt the plasma, allowing for a longer duration of hot, dense plasma capable of fusion conditions, or rapid chemical reactions.

The RF generators 102 may be Magnetron type, solid state type, Klystron type, Inductive Output Tube type, or other type sources of high-power RF energy. RF may be delivered to the RF applicator(s), e.g., by waveguide, coaxial cable, or strip line. An RF tuner ensures delivery of RF power to an RF concentration zone 110 within the atmospheric isolation device by matching the impedance of the RF generator to the RF distributor 108 and/or RF applicator(s) 107. The tuner 106 may be adjustable, fixed, motorized, or motorized automatic. Each RF generator 102 or group of RF generators 102 may optionally feed a circulator preventing or reducing feedback of RF to the generator. In some implementations, the RF applicator 107 may include a resonator (resonance cavity), which serves to intensify the RF field by a factor of up to 10⁶ in a localized region (e.g., corresponding to the area of the pinch or RF concentration zone 110). The RF resonator may be configured to operate in the transverse electromagnetic (TEM) mode, transverse electric (TE), or transverse magnetic (TM) modes, such as 01, 11, 12, 31, 02, 03, 123 etc., and may be circular, rectangular, octahedral, spherical, or other suitable shape. In alternative implementations the RF applicator 107 may utilize parallel plate electrodes or an inductive coil to deliver RF energy to the plasma. Parallel plate electrodes or an inductive coil may be backed by an LC resonator circuit to boost no-load electric field. The LC resonator circuit, sometimes called a tank circuit, includes an inductor and capacitor connected in a closed loop. The parallel plate electrodes act as the capacitor. The electric field between the plates is maximized when the resonator circuit is driven at its resonant frequency, which is proportional to the inverse of the square root of the product of the capacitance C of the parallel plate electrodes and the inductance L of the inductor.

In some cases, the one or more RF applicators 107 may be configured to direct RF energy from the RF generator(s) 102 radially inward toward the volume where the Z-pinch can be formed between the cathode and anode. As used herein, the term “Z-pinch zone” refers to a column of space in the reactor where the Z-pinch can occur or is occurring. The Z-pinch zone may lie within or may overlap the RF concentration zone 110. The RF Distributor 108 distributes RF power to one or more entry points on the RF applicator(s) 107, which delivers RF energy to RF concentration zone 110. The RF distributor 108 may be configured to ensure that the RF applicator(s) 107 distributes power to the Z-pinch plasma in a cylindrically uniform manner. For example, the RF distributor 108 can include one or more waveguide entries arranged in a mirrored linear pair, triangle, square, pentagon, hexagon, septagon, octagon, or higher order polygon geometry. The RF applicator(s) 107 may be made from copper, aluminum, stainless steel, or other conductive metal, or material coated with conductive metal or other high conductivity materials.

In some cases, the Z-pinch electrodes (e.g., electrodes 104, 105 in FIG. 1A) are omitted, and the plasma is formed in the RF concentration zone 110 by delivering energy from the RF distributor 108. In some cases, the delivered RF energy can induce a Z-pinch current in the plasma column. The alternating current (AC) in the plasma column can induce a Z-pinch in the plasma column due to the forces created by the current, as described herein. In some cases, the Z-pinch current induced in the plasma column flows primarily through a skin of the column. For example, the RF energy can induce high frequency AC current in the plasma column, which can be conducted primarily along the skin of the column. In some cases, the energy application area of the plasma is confined in the axial direction to a length of less than ½ wavelength of the applied RF frequency (e.g., a length of less than about 16 cm for a frequency of about 915 MHz). In some cases, the RF induced axial current can be used to drive Ohmic heating of the plasma to achieve temperatures of 0.3e V to 30e V.

According to aspects of the present disclosure, a plasma in the RF concentration zone 110 is “lit”, i.e., initiated, in the reactor prior to the application of Z-Pinch current. This creates a uniform smooth skin plasma which reduces seed sites at which MRT instabilities can form. The RF energy may be reduced, turned off, maintained, or increased during the period of the Z-Pinch, or pulsed periodically or pulsed in coordination with relevant phases of the Z-Pinch. In some embodiments RF energy may be maintained continuously during the Z-Pinch and responsible for continued instability mitigation by naturally directing energy to the instability “seeds” (initiation of instabilities). In some implementations, the plasma in the RF concentration zone 110 may be contracted into a narrow cylinder by means of its own natural form, or by means of an externally applied magnetic field, (another mode of operation) even without the Z-Pinch current. Contracting the plasma in this manner can set up a column for the Z-Pinch ahead of time and make instabilities less likely compared to, e.g., having the plasma uniform through the reactor.

Z-pinch plasma may experience instabilities detrimental to its intended purpose. As used herein, the term “plasma instabilities” generally refers to regions of a plasma where geometric distribution of active species deviates from axisymmetry and axial uniformity, e.g., due to changes in characteristics of the plasma, such as temperature, density, electric fields, and magnetic fields. These instabilities can cause localized regions of the plasma to move differently than surrounding regions. This can lead to uneven particle flow or the formation of plasma filaments. In an alternative implementation, the RF may be applied to regions of plasma instability only during Z-pinch formation to “treat” the instabilities where the RF preferably concentrates, preventing them from collapsing the pinch. In another alternative implementation, the RF may be applied only during stagnation, i.e., after compression has stopped following initiation of the Z-pinch, so as not to disrupt the Lorentz magnetic force responsible for the implosion. In a further alternative implementation, the RF may be applied to pre-ionize the plasma, unapplied during implosion, and reapplied during stagnation.

The atmospheric isolation device 109 is configured to maintain a controlled environment for the Z-Pinch, and a gas delivery and/or recirculation device for providing more fuel or reactant to the Z-Pinch plasma activation area. Atmospheric isolation device 109 may include, e.g., a vacuum/pressure chamber, or gas curtain. A gas source may supply fusion reactant gases to an enclosed environment, such as a chamber, in which the Z-pinch takes place. In FIG. 1A, a dashed line indicates the enclosed environment. An exhaust system, e.g., one or more vacuum pumps, may remove gas at a desired rate to maintain the desired pressure of the atmosphere in the enclosed environment. The system 100 may further include an energy extraction mechanism 120 configured to extract energy from nuclear fusion resulting from a Z-pinch occurring in the Z-pinch plasma column. By way of example, the energy extraction mechanism 120 may include a neutron absorbing blanket containing, e.g., lithium, lead, or water, that is heated by transfer of kinetic energy of the neutrons impacting it. A cooling mechanism uses a coolant (e.g., molten salt, helium, water, or liquid metal) extracts the heat. For example, the hot coolant may drive a heat exchanger, which generates steam to spin a turbine for electricity production. In some implementations, the energy extraction mechanism may include a downstream nuclear fission reactor that uses lithium-7 as the fissionable fuel. Neutrons produced by fusion in the Z-pinch plasma column may drive fission of the lithium-7 and energy may be extracted from the fission reaction, e.g., through a heat exchanger that drives a turbine. In alternative implementations, the energy extraction mechanism may include a neutron absorbing blanket of a precursor isotope for a useful product isotope. By way of example, and not by way of limitation, the precursor isotope may be molybdenum-98 that is used to make molybdenum-99, which in turn decays to form technetium-99 m, a medical isotope.

FIG. 1A shows an example of application of RF to an idealized stabilized plasma column in the RF concentration zone 110 constrained between parallel plates. Transverse Electromagnetic (TEM) mode RF radiation may be applied in a radially symmetric manner to the plasma column. Two or more converging transverse electric (TE) modes may also be applicable if oriented with the magnetic field of the RF waves from the RF applicators wrapping around the pinch plasma, and Electric field aligned with the axis of the pinch plasma.

There are many variations on the system 100 depicted in FIG. 1A. For example, the RF distributor 108 and environmental separation window 111 can be configured so that RF radiation enters the chamber 109 from its floor. There may be one or optionally two or more RF generators 102, tuners 106, distributors 108, and windows 111 configured to introduce RF power to the chamber in this manner. The RF distributor(s) 108 may be simple waveguide structures coupled between the tuner(s) 106 and window(s) 111, or optionally configurations of dielectric RF lenses or magnetized permeability change material devices such as electromagnet magnetized ferrite. In this implementation, the chamber 109 itself is configured to act as the RF applicator 107. This may be accomplished, e.g., by making the chamber wholly or partially of an electrically conductive material, such as aluminum, stainless steel or copper. By introducing RF power through the chamber floor, the chamber/applicator may distribute RF waves from one or more points of entry proximate to the anode 105 and cathode 104. In this example, the anode 105 is located within chamber 109 and the cathode is located outside the chamber (or mostly outside of the chamber).

FIG. 1B shows a schematic of an example of an RF stabilized plasma system 10, in accordance with some embodiments. The system in FIG. 1B can produce a dense plasma 12 that can be used to form one or more output products from one or more input reactant materials using the RF stabilized plasma (e.g., a Z-pinch plasma, or a vortex stabilized plasma) confinement systems described herein. The plasma forms active species, also referred to as a product stream, from input reactants, and then outputs the active species into a downstream growth chamber where the output products are formed. The system in FIG. 1B can include a plasma chamber, optionally including Z-pinch electrodes (an anode 20 and a cathode 22), where the plasma chamber 16 is coupled to an RF generator 58. A plasma formed in the plasma chamber can be densified using an RF field generated by the RF generator, and an axial force generated by current from the Z-pinch electrodes (labeled as “anode” 20 and “cathode” 22 in FIG. 1B).

A reactant inlet 28 into the plasma chamber, introduces reactant 36 (e.g., methane, ethane, propane, or other hydrocarbons) into the plasma where it can be converted into active species in the plasma. In some cases, solid reactants such as powders, rods, plates, or other form factors can be used. In some cases, powders or particulate reactants can be introduced into the plasma using a powder feed system (e.g., powder feed 56 in FIG. 1B). For example, carbon powder (e.g., carbon black and/or graphite), or plastic particulates could be used as sources of carbon. In other cases, a rod of material can be mounted such that material from the rod is removed by the plasma and the removed material is used as a reactant. For example, a graphite rod mounted such that it protrudes into the plasma could be used as a source of carbon reactant material. The reactant inlet can be a set of inlets in some cases.

The gas inlets, including the reactant inlets and/or other gas inlets are used to form the funnel creating the pressure gradient at the core. An outlet from the plasma chamber (through a hole in the cathode in this example) allows the active species to leave the plasma chamber. In some cases, the output 40 is designed as a nozzle to direct and shape the flow of the output species. System 10 can include an optional recirculating gas flow apparatus 34 for efficient gas usage, in some cases, where gases can be recirculated using a pump 32 from outlet 40 of the chamber to reactant inlet 28.

The system shown in FIG. 1A may operate under direction of a system controller 101. Such a controller 101 may include one or more computing devices, microprocessors, microcontrollers, application specific integrated circuits. The controller 101 may be coupled to the RF generator(s) 102 and the pulse power supply 103. The controller 101 may be operably coupled to various components of the system 100 to coordinate delivery of fuel gas, RF power, pulse current to the RF concentration zone 110. For example, the controller 101 may provide signals that trigger the RF generator(s) 102 to turn on and generate RF waves prior to triggering the power supply 103 to apply a DC pulse between the cathode 104 and anode 105 to pre-ionize a plasma discharge and to turn off the RF waves prior to the DC pulse, or turn on when the DC pulse is delivered, or turn on prior to the DC pulse and turn off after the DC pulse is complete, or turn on prior to a series of pulses and turn off after the series is complete. In other implementations RF may be used to trigger plasma formation which triggers discharge of DC from the DC pulse delivery device, with the RF acting as a switch. Alternatively, plasma formation initiated by the RF may trigger a separate switch such as spark gap, solid state switch, MOSFET array, ignitron, contact, or other high voltage high current switch.

In some implementations, the controller 101 may be configured to cause the pulse power supply 103 to deliver a series of pulses of different amplitude, frequency, period, pulse shape, waveform, or pattern between the anode 104 and cathode 105, thereby delivering controlled current pulses to the Z-Pinch Plasma column, e.g., to facilitate stabilization, heating, or density control. In some implementations, the pulse power supply 103 may take a form largely resembling a Linear Transformer Driver System. In other embodiments it may take the form of a programmable Marx generator array, optionally impedance tuned, optionally with variable impedance for various plasma operating conditions. In some embodiments, the system further includes a controller (e.g., controller 101) operatively coupled to the substrate holder and associated motion systems, including one or more motors, rotary feedthroughs, and translation stages, and configured to control the orientation of the substrate holder relative to the plasma deposition jet. The controller may coordinate rotation of the substrate about one or more axes, including continuous or indexed rotation about a central shaft, as well as angular positioning (e.g., tilt, pitch, and yaw) of the substrate holder to adjust an angle between a substrate surface and the plasma deposition axis. The controller may further control translational motion of the substrate holder in one or more linear directions (e.g., X, Y, and Z axes) via a translation stage, thereby enabling precise positioning of the substrate relative to the plasma jet. In some cases, the controller synchronizes orientation and position of the substrate holder with plasma operating parameters, including RF power, gas flow rates, and reactant delivery, to achieve controlled deposition profiles, uniform coating thickness, or patterned material growth. The controller may also adjust rotational speed, angular orientation, and translation dynamically during deposition to form complex geometries, including cylindrical, contoured, or free-standing structures, and to maintain desired deposition conditions such as temperature, exposure time, and incident flux of active species as further discussed below.

In some embodiments, the controller operates in a closed-loop configuration using feedback from one or more sensors. Such sensors may include temperature sensors, optical emission spectroscopy systems, imaging systems, deposition thickness monitors, or other diagnostic tools configured to characterize the plasma and/or deposited material. The controller may adjust one or more parameters, including plasma power, gas flow rate, substrate motion, or reactant delivery, in response to the sensed data to maintain desired deposition conditions or to correct for deviations during operation. In some embodiments, the controller is configured to adjust one or more process parameters as a function of a geometry of the deposited structure. For example, the controller may vary substrate rotational speed, translation speed, plasma power, or reactant flow rate based on a local diameter, curvature, thickness, or feature size of the structure being formed. Such geometry-dependent control enables uniform deposition, controlled material properties, and fabrication of structures with varying cross-sections or complex geometries.

In some embodiments, the controller is configured to execute a predefined or dynamically generated toolpath that defines relative motion between the plasma jet and the substrate. The toolpath may be specified using digital design data, such as computer-aided design (CAD) models, and may include coordinated motion in multiple axes to produce complex three-dimensional geometries. The controller may further modify the toolpath during operation based on process conditions or feedback data. In some embodiments, the controller synchronizes operation of multiple subsystems, including plasma generation, reactant delivery, substrate motion, and environmental control systems. Synchronization may include coordinated timing and adjustment of RF power, current, gas flow, pressure, and mechanical positioning to maintain desired deposition characteristics such as temperature, composition, and growth rate. In some embodiments, the controller dynamically modifies deposition parameters in real time in response to changes in measured conditions or predicted process outcomes. Such adaptive control may include adjusting plasma intensity, modifying reactant composition, or altering motion trajectories to maintain uniformity, compensate for disturbances, or achieve target material properties.

The system in FIG. 1B, shows an example where the reactant includes a reactant inlet 54 capable of introducing a reactant into the plasma. The reactant inlet 54 is provided with solid material from a powder feed 56, in some cases. This system is capable of forming particles including a mixture, or a composite material, of an output product (produced from the inlet reactants) and the reactant. For example, the reactant can include iron oxide in the form of iron oxide particles. Hydrogen gas can also be added, for example through the reactant supply 36. Methane gas can be added to the downstream reaction chamber, and the product can be solid carbon steel (e.g., particles).

The plasma column 12 can be stabilized and/or densified by application of RF power (“RF Wave” in FIG. 1B) from the RF generator 58. In the illustrative embodiment, the RF power can be input into the isolation container 16 from the lateral sides to apply RF power to stabilize the plasma column 12. RF power can be introduced through a separation window 24 of the isolation container 16 and be delivered to the plasma column 12. The metal reactant inlet 54 is coupled to a solid powder feed 56 for introducing solid materials into the isolation container 16. The solid feed system is configured to provide powdered materials, such as powdered metals, oxides, nitrides, carbon, or powders of other elements, into the plasma column 12 to serve as solid reactants or to generate composite materials.

FIG. 1C shows a schematic of an example of an RF stabilized plasma system 101, in accordance with some embodiments. The system in FIG. 1C is similar to the system 10 shown in FIG. 1B, and it can also produce a dense plasma 12 that can be used to deposit materials (such as diamond, or diamond metal composite materials) on a substrate using the RF Z-pinch plasma confinement systems described herein. The deposition is laterally constrained and therefore, the system can act as a 3D printer when the substrate is supported by a moving stage 46. Stage 46 may also be referred to as a substrate holder. The system in FIG. 1C can include a plasma chamber 116 including Z-pinch electrodes 120, 122 coupled to power supply 18 (e.g., an AC current generator), where the plasma chamber is coupled to an RF generator 58. The anode 120 and the cathode 122 Z-pinch electrodes in this example extend into the chamber 116 containing the plasma 12, as shown in the figure. A plasma formed in the plasma chamber can be densified using an RF field generated by the RF generator 58, and an axial force generated by current from the Z-pinch electrodes. As in system 10 in FIG. 1B, a reactant inlet into the plasma chamber, introduces reactant (e.g., methane, ethane, propane, or other hydrocarbons) into the plasma where it can be converted into active species in the plasma. The reactant inlet can be a set of inlets in some cases. The gas inlets including the reactant inlets and/or other gas inlets can be used to form a funnel creating the pressure gradient at the core. An outlet from the plasma chamber (through a hole in the cathode in this example) allows the active species to leave the plasma chamber. In some cases, the output is designed as a nozzle to direct and shape the flow of the output species. A substrate is positioned adjacent to the nozzle such that the active species form a material comprising diamond on the substrate.

The system in FIG. 1C shows an example where the substrate is mounted to a moving or rotating mount such that plates, tubes, or other structures can be formed on the substrate. In other cases, the substrate can be a rotatable cylinder. As in the system 10 shows in FIG. 1B, system 101 in FIG. 1C can also include a metal reactant inlet coupled to a metal powder feed capable of introducing metal reactant into the plasma. With such an inlet into the chamber, system 101 in FIG. 1C is also capable of forming a composite material of diamond and the metal on the substrate. For example, the composite material can include diamond and tungsten or diamond and copper. Systems 10 and 101 in FIGS. 1B and 1C each include an environmental separation window 24 to separate the RF generator 58, RF tuner 62, and RF distributor 64, from the chamber 16, 116 containing the plasma and reactants. The RF applicator 66 can in inside the chamber 16 in some cases. Systems 1000 and 1001 in FIGS. 1B and 1C each include a power supply (e.g., a pulsed DC power supply) coupled to the Z-pinch electrodes (anode and cathode) to supply the Z-pinch current to the electrodes.

In the system illustrated in FIGS. 1B and 1C, substrate 48 is positioned on substrate holder 46, which supports the substrate during deposition and may include mechanisms for rotation and/or translation. The substrate holder 46 is operatively coupled to a positional system 50 configured to provide motion in one or more axes, including X, Y, and Z directions, as well as rotational motion about one or more axes (e.g., theta rotation). The positional system 50 enables controlled movement of the substrate relative to the plasma output to facilitate additive manufacturing and patterned deposition. A recirculation and exhaust system including pump 32 and associated flow paths 34 is configured to remove process gases and byproducts from the chamber and, in some embodiments, recirculate one or more gases back into the system to improve efficiency and control gas composition.

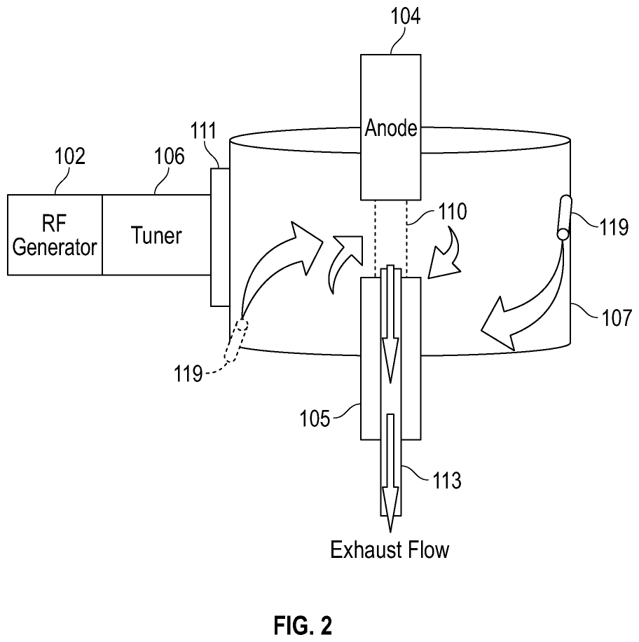

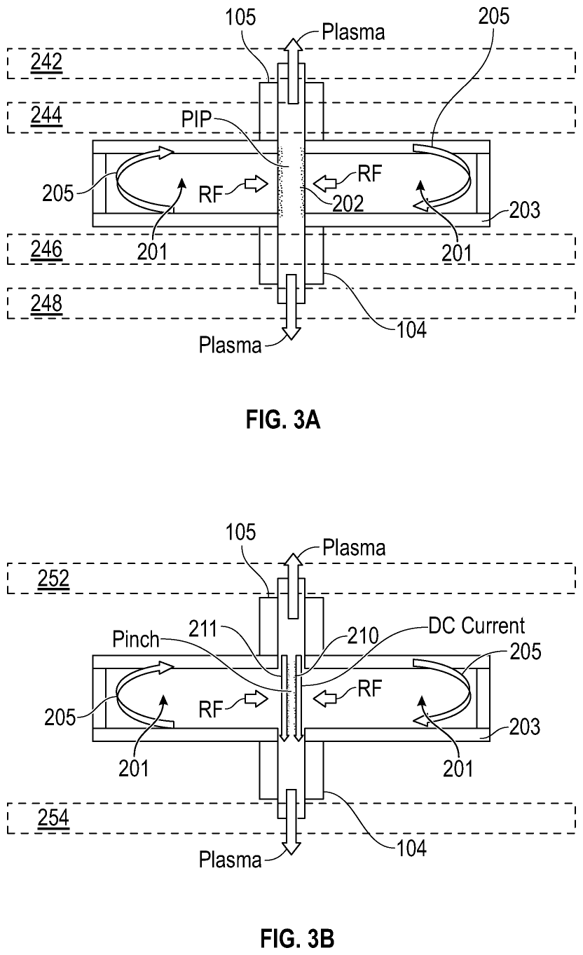

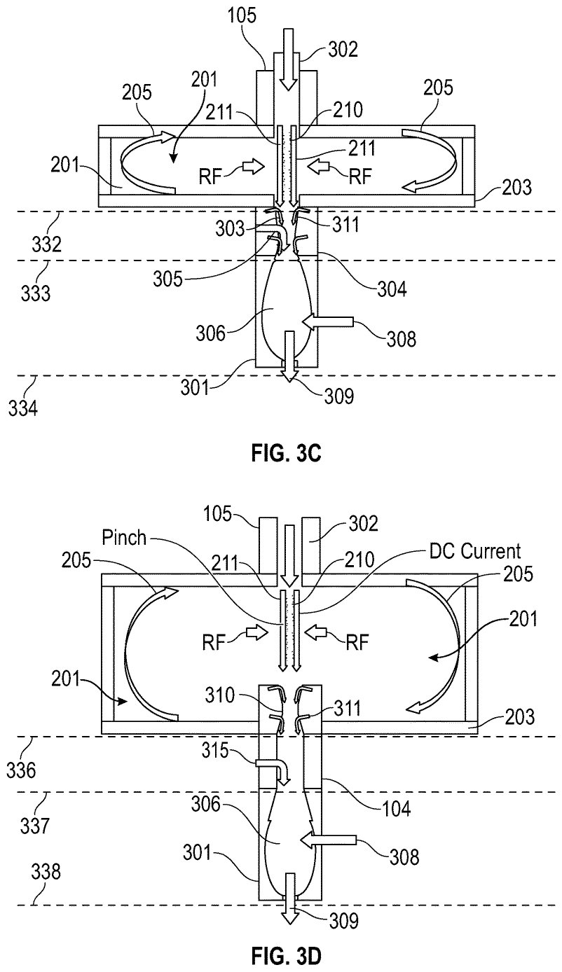

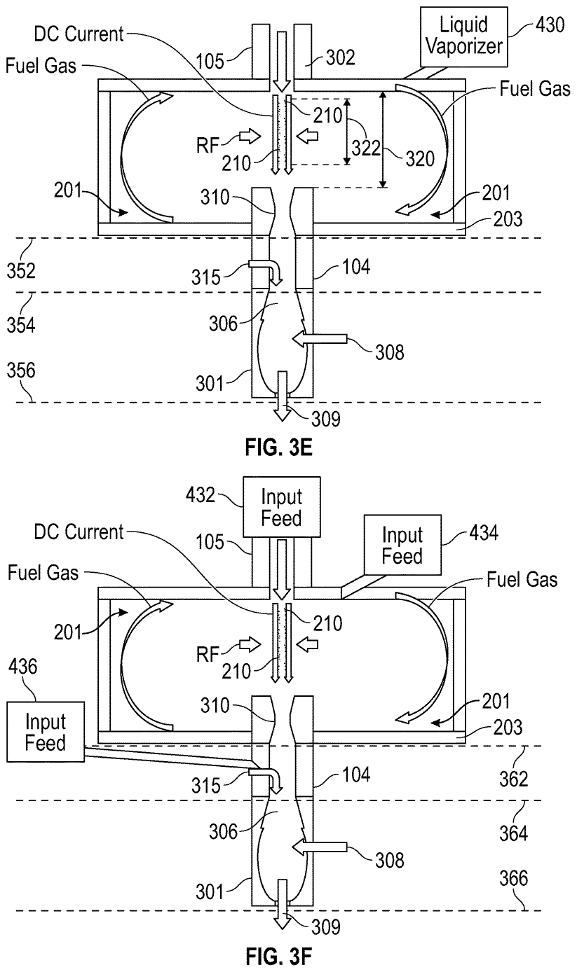

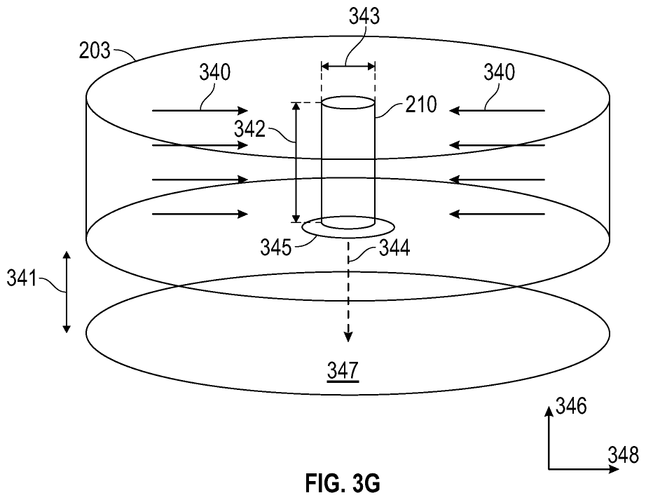

FIG. 2 illustrates an example of an alternative system configuration where tangential gas injectors 119 cause a vortex flow pattern within the chamber 109. The gas injectors may be angled tangentially with respect to a symmetry axis of the chamber so that vortex flow is present proximate to the center of the chamber. In this example, an exhaust tube 113 is coaxial with the cathode 104. In some implementations, an exhaust tube may optionally be coaxial with the anode 105. In other implementations, there may be two or more exhaust tubes, with one coaxial with the cathode and another coaxial with the anode. It should be appreciated that implementations of the type shown in FIGS. 3A-F include those in which a single structure acts as both electrode (anode or cathode) and exhaust tube.

In some implementations, e.g., as depicted in FIG. 3A-F, the controller may be configured to cause the RF generator(s), RF applicator(s) and RF distributor to apply sufficient RF energy to a neutral gas 201 in the Z-pinch plasma column region 202 to create a plasma prior to the Z-pinch drive device applying electric current through the Z-pinch plasma column, e.g., as shown in FIG. 3A. In alternative implementations, the controller may be configured to cause the RF generator(s), RF applicator(s) and RF distributor to apply RF energy to the Z-pinch plasma column 210 as the Z-pinch drive device applies electric current 211 through the Z-pinch plasma column 210, e.g., as shown in FIG. 3B. It is noted that combinations of such implementations are possible, e.g., combinations where the controller is configured to cause the RF generator(s), RF applicator(s) and RF distributor to apply sufficient RF energy to a neutral gas in the Z-pinch plasma column region to create a plasma prior to the Z-pinch drive device applying sufficient electric current through the Z-pinch plasma column and to subsequently apply RF energy to the Z-pinch plasma column as the Z-pinch drive device applies sufficient electric current through the Z-pinch plasma column.

FIG. 3A depicts a reactor in the form of an RF resonator 403, providing up to, e.g., 1 kW/mm3 of RF power to the pinch zone 202 prior to the pinch. Not to be limited by theory, providing this energy prior to the pinch may create a plasma in the area of the pinch zone 202 that mitigates the nucleation of MRT instabilities by removing the field emission and Townsend avalanching phases of ionization necessary with a pure DC pulse ionization. In some embodiments, the gas injectors may be angled tangentially with respect to a symmetry axis of the chamber so that vortex flow of fuel gas 205 is present proximate to the center of the chamber. Furthermore, as illustrated in FIG. 3B, the RF wave continues to act exclusively on the outside of the pinch cylinder, the area of trouble with respect to cooling by neutrals and formation of MRT nucleation sites, without interfering with the denser core of the plasma. In some implementations, the RF resonator 403 may be integrated into the atmospheric isolation device.

FIG. 3C and FIG. 3D depict reactors configured to take part in plasma driven reactions according to aspects of the present disclosure. In FIG. 3C the atmospheric isolation device 203 may be attached to one or more down-stream reaction chambers 301. In the implementation shown an inlet of the downstream reaction chamber 301 is connected to an outlet of the atmospheric isolation device 203 aligned with an axis of the Z-pinch plasma column region 210. The outlet of the atmospheric isolation device 203 is coupled to the cathode 304 used for the DC pulse. A carrier gas and/or reactant gases and/or downstream reagents may be introduced at an inlet 302 opposite the outlet for the downstream reaction chamber 301 to push concentrated plasma towards the outlet of the downstream reaction chamber 301. This may allow for collection of products 309 at the downstream reaction chamber 301. In some implementations, the downstream reaction chamber may be coated with a catalyst such as tungsten, Iron Oxide, Alumina, CaO, or Ru on C or MgO. In some implementations, the reaction chamber may have features providing additional surface area such as metal wool or fins. The downstream reaction chamber may be water cooled to promote rapid cooling of reaction products.

The implementation shown in FIG. 3C further includes a venturi nozzle 303 incorporated into a plasma outlet of atmospheric isolation device 203 and located on the outside of the atmospheric isolation device 203. In alternative implementations, there may be one or more plasma outlets patterned in a rotationally symmetric array around a cathode and/or an anode. As noted above, an RF resonator may be integrated into the atmospheric isolation device. The venturi nozzle shown here is electrically conductive and integrated with the cathode 304. The venturi provides suction to move plasma species out of the chamber to be reacted. The venturi may also facilitate effective mixing of a downstream reagent.

In FIG. 3D the venturi nozzle 310 is mounted on the inside of the atmospheric isolation device 203 before the outlet. A flow of venturi fluid 311 may be introduced through inlets just before or after the narrow “throat” of the venturi nozzle 310 to flow along the inner wall of the venturi nozzle toward the downstream reaction chamber. The venturi fluid 311 may be a neutral gas, such as argon or helium, or a reactant gas such as hydrogen, nitrogen, methane, or carbon monoxide that participates in a reaction in the downstream reaction chamber 301. In alternative embodiments the venturi fluid 311 can be a reactant liquid such as deionized water which is reacted with nitrogen plasma to form nitric acid, or a sulfur dioxide plasma to form sulfuric acid. In alternative embodiments the venturi fluid 311 can be a heat transfer fluid liquid such as supercritical CO2 which rapidly cools the plasma stream. The gas flowing along the inner wall of the venturi nozzle 310 may entrain the plasma to a narrow stream by following the sidewalls of the venturi nozzle 310. Entraining the plasma in this fashion may keep the hot plasma away from sides of the down-stream reaction chamber. In other embodiments, venturi fluid may be used to rapidly cool the plasma to stabilize desired reaction products. In some embodiments the venturi fluid 311 may be used to thoroughly mix the plasma species with a second reagent, reacting to form a desired product.

In FIGS. 3A-3D, various reference numerals identify functional regions of the plasma and flow structure. The reference numeral 302 denotes a direction of reactant or carrier gas flow into or through the system. The reference numeral 310 denotes a non-equilibrium excitation region in which plasma species are energized and chemical reactions are initiated or enhanced. The reference numeral 304 denotes a reaction pathway or region through which vibrationally excited or otherwise activated chemical species travel and undergo transformation. The reference numeral 320 denotes an overdense plasma region characterized by elevated plasma density and energy relative to surrounding regions. These regions may overlap spatially or be distributed along the plasma column depending on operating conditions and system configuration.

In some implementations, downstream reagents 305 may be introduced with a carrier gas at the carrier gas entrance 302, into a stream of primary reactants forms the Z-pinch plasma column 210, at the entrance to the venturi nozzle, the pinch of the venturi nozzle and/or the exit of the venturi nozzle. One or more holes in the interior walls of the venturi nozzle 303 may be used to introduce the downstream reagents into the plasma. The one or more holes may be connected via pipes or tubing to tanks which contain the downstream reagents. The one or more downstream reagents may be liquid, gas or an aerosolized liquid. The downstream reagents react with the primary reactants flowing from the Z-pinch plasma column 210 in the downstream reaction chamber 301 to form dissociated products. The dissociated products may then be further reacted with secondary reactants 308 to form final or intermediate products. The final products 309 of the reactions with the secondary reactants 308 and dissociated products may exit the downstream reaction chamber 301 via an exit orifice for collection or further processing. In some implementations, a secondary plasma 306 may be generated in the downstream reaction chamber to facilitate reaction between the downstream reagents, and/or dissociated products and/or secondary reactants.

In another example implementation, as shown in FIG. 3D, the downstream reagents 315 may be introduced through holes in the hollow cathode 104 connected to the downstream reaction chamber. Alternatively, the one or more downstream reagents may be introduced into the atmospheric isolation device with the fuel or reactant gas or in separate inlets from the inlets introducing fuel gas. In yet other alternative implementations, the one or more downstream reagents may be introduced over the outlet for the plasma with or without a carrier gas. A carrier gas may be introduced to the atmospheric device to push the plasma column towards the plasma outlet. In some implementations the carrier gas may be introduced over the plasma outlet through a carrier gas inlet 302. The downstream reaction chamber 301 may be a container suitable to contain secondary reactions that occur after the concentrated plasma reactions. The downstream reaction chamber may have inlets to introduce secondary reactants 308 to the downstream reaction chamber. These secondary reactants 308 may react with products formed from reactions between the concentrated plasma. The final products 309 of these secondary reactions may be collected from the downstream reaction chamber or may flow through a collection outlet to a separate collection area (not shown).

For example and without limitation, downstream reagents such as polymers, water, or hydrocarbons may be introduced to the compressed plasma column. The downstream reagents may react with a compressed plasma column resulting in dissociated products such as dissociated hydrocarbon radicals. These products may then react with the secondary reactants in the downstream reaction chamber. By way of non-limiting example, the secondary reactants may include Nitrogen (N2) and Oxygen (O2) resulting in the formation of Nitric Acid, HNO3, from the dissociated water radicals. The final product, Nitric Acid, may be collected from the downstream reaction chamber or flowed to a collection area. In another example the downstream reagents may include simple molecules such as water (H2O) and carbon dioxide (CO2) which may be dissociated in the plasma column into their constituent atoms and may recombine into complex hydrocarbons which may end up in the downstream reaction chamber. Thus, an advantage of the compressed plasma reactions described herein is that they may be used to create compounds which typically require thermodynamically unfavorable reactions.

It is noted that although an anode 104 and a cathode 105 are depicted in FIG. 3C and FIG. 3D aspects of the present disclosure include implementations that either omit them or that do not involve applying a voltage between them to produce a Z-pinch current. As such, the anode and cathode may be regarded as optional features for implementations involving chemical processing, including implementations involving plasma driven reactions using downstream reagents, among others. In particular, aspects of the present disclosure apply to implementations in which chemical processing may occur without the need for a Z-pinch current to compress a plasma column. Fuel, reactant, or downstream reagents may be solid, liquid, or gas at room temperature. Fuel, reactant, or downstream reagents may be a superfluid, such as superfluid helium-4. For example but not by limitation, fuel or reactant gas can be heated to above its boiling point at the pressure within the atmospheric isolation device before entry into the atmospheric isolation device 203, optionally by absorbing heat from the atmospheric isolation device, anode 104, or cathode 105. By way of example, elemental sulfur could enter the system at 1 bar and 115 °C in the liquid phase, and be heated to above 444 °C by way of contact with hot components. Downstream reagents entering the downstream reaction chamber 301, may be gas, liquid, or solids at room temperature. In some implementations, fuel, reactants, or downstream reagents may be in the form of solid particles or liquid droplets that are small enough to be entrained in a gas flow, e.g., sub-micron particles or impurities. Examples of liquid fuel, reactant, or downstream reagents include liquids at room temperature, mixtures which are liquid in the temperature range of the atmospheric isolation device or other components, or liquids which include dissolved or suspended solids, such as a Lithium Hydroxide solution. Downstream reagents, carrier, fuel, and reactant gasses may be injected in interchangeable orientations, by way of example, in FIG. 3B Fuel gas could be injected at Carrier Gas Entrance 302, or carrier gas could be injected at port for Secondary Reactants 308. By example, a downstream reagent may include:
water, entering 1 atm pressure environment in the reagent chamber at 1 to 100 °C in the liquid phase, or 101 °C to 650 °C in the gas phase as steam
Iron oxide powder or Wolframite at fluidizable particle size carried by hydrogen gas at 20 °C
Oxygen entering a 5 atm pressure environment in the liquid phase between −227 °C and −160 °C, or in the gas phase above −160 °C

As used herein, particles are said to be fluidizable if their size and density allows them to become suspended and behave like a fluid when a gas or liquid flows through them. The degree to which particles may be fluidized depends mainly on particle size, density, and fluid velocity. Particles that are too small may tend to stick together. Particles that are too large may require an impractically large fluid velocity.

Table 1 shows several examples of reactions which can be driven by the plasma.

TABLE 1

| | Downstream | |
|---|---|---|
| Fuel/Reactant Gas | Reagent | Product |
| nitrogen + oxygen | water | nitric acid |
| nitrogen | hydrogen | ammonia |
| carbon dioxide | hydrogen | methanol and water |
| methane and water | none | methanol |
| sulfur and hydrogen | water | sulfuric acid |
| methane | none | graphite and hydrogen |
| carbon dioxide | nitrogen | carbon monoxide, |
| | | nitric oxide |
| iron oxide and hydrogen | methane | carbon steel |
| methane | oxygen | water, carbon |
| | | dioxide, energy |

In some alternative implementations the plasma species may include nitrogen and oxygen, forming nitrogen oxides. In other alternative implementations the plasma species may include air, forming nitrogen oxides. In still other alternative implementations the plasma species may be air supplemented with nitrogen and/or oxygen, forming nitrogen oxides.

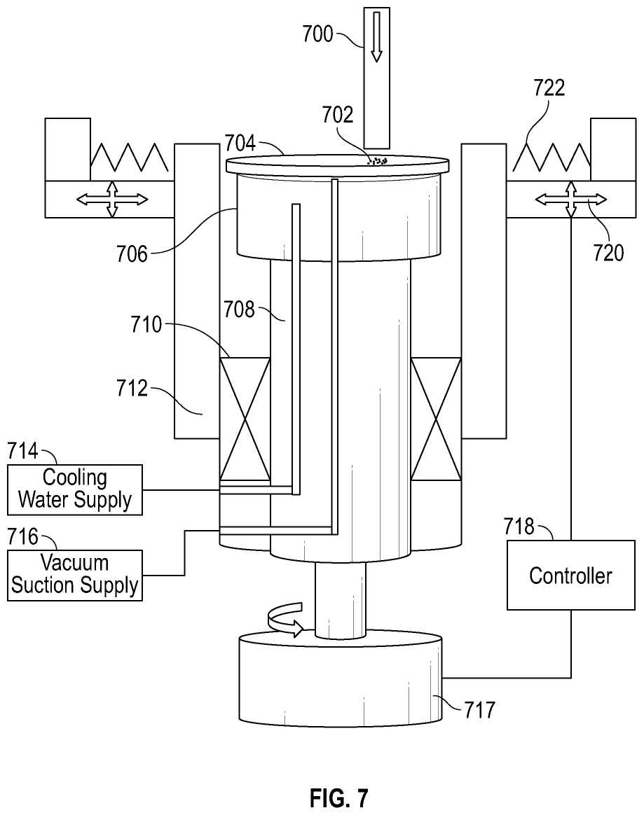

Dotted boxes 242, 244, 246, and 248 of FIG. 3A, and 252 and 254 of FIG. 3B, 332represent possible positions for substrate holder systems in FIGS. 3A-3B (e.g., as explained in FIG. 7-10). Dotted lines 333, and 334 of FIG. 3C, and 336, 337, and 338 of FIG. 3D, 352, 354, and 356 of FIG. 3E, and 362, 364, and 366 of FIG. 3F represent possible positions for substrate deposition surfaces in FIGS. 3C-3F. For example, if a position like 244 is used in FIG. 3A, then all downstream components, i.e., the hollow anode 105 is omitted. In some cases, no current is flowing between top and bottom cathode (i.e., there is no Z-pinch current) and therefore the anode and/or cathode are not necessarily needed. FIG. 3B shows an external Z-pinch current flowing between the anode and the cathode. Note however that the “RF” energy can itself induce a Z-pinch current in the plasma. Therefore, even without the anode and/or cathode 104/105 present, the plasma 202 in FIG. 3A can still have a Z-pinch current (e.g., oscillating up and down in the plasma column at the frequency of the RF excitation).

FIGS. 3A-3F show positions of additional liquid or solid materials inputs. For example, if a substrate position such as 362 is used in FIG. 3F, then the input feed 436 would be omitted, and either 432 or 434 can be used. Input 308 can only be used with positions 356/366. Dotted boxes represent possible positions for substrate deposition position, like 332 is used, then all downstream components, i.e., the hollow cathode 304 and surfaces. For example, if position 332 (FIG. 3C) is used then all downstream components, i.e., the hollow cathode 304 and the downstream reaction chamber 301 can be omitted. In some cases, no current is flowing between top and bottom cathode (i.e., there is no Z-pinch current) and therefore both anode and cathode are not necessarily needed. FIGS. 3E and 3F show positions of additional liquid or solid materials inputs. For example, if a substrate position such as 362 (FIG. 3F) is used, then the input feed 436 would be omitted, and either 432 or 434 can be used. Input 308 can only be used with positions 356/366 in some embodiments. It should be appreciated that the farther away from the plasma column in the chamber that the substrate is, the colder the reaction products will be before forming the deposited film. FIG. 3E may also have an optional liquid vaporizer 430 for a fuel/reactant liquid. In FIG. 3E a liquid fuel/reactant can be fed into the atmospheric isolation chamber 203 and then be converted into active species in the plasma 210. Isolation chamber 203 may be referred to as a plasma chamber. In other cases, a fuel/reactant liquid can be fed into the hollow anode 105, and the heat from the electrode 104 can vaporize the liquid before it reaches the atmospheric isolation chamber 203. In other cases, a fuel/reactant liquid can be fed into the downstream reagents 315, and the heat from the nozzle 310 and/or the electrode 104 can vaporize the liquid before it reaches the downstream reaction chamber 301 or can react with the active species from the plasma output from nozzle 310. In yet other cases, liquid droplets of fuel/reactant can be entrained in a carrier gas (e.g., using a heated bubbler) and the liquid droplets can be vaporized by the plasma 210.

FIG. 3F includes examples of optional input material feeds 432, 434, and/or 436, which can be gas inputs, liquid inputs, or solid powder feeds that can be used to introduce powders at different locations within the system. Input material feed 432 feeds gaseous, liquid, or solid material through the hollow electrode 104 into the plasma 210. Input material feed 434 feeds gaseous, liquid, or solid material into the plasma 210 through a separate chute that is coupled to the atmospheric isolation chamber 203. Input material feed 436 feeds gaseous, liquid or solid material into the downstream reagents 315, to react with the active species from the plasma in downstream reaction chamber 301.

FIG. 3G shows a schematic of an example of an atmospheric isolation device 203 containing a plasma column 210. RF power 340 is applied to the plasma column 210 (e.g., as described herein). In some cases, the RF power 340 applied to the plasma column 210 is approximately cylindrically symmetric. The RF power is applied to a concentration zone, which is approximately coextensive with the plasma column 210, in some cases. The plasma column 210 can be confined in a radial direction and in the axial direction. A radial direction is shown as direction 348, and the axial direction is shown as direction 346. Other radial directions are those that are perpendicular to the axial direction 346. In some cases, the RF power 340 can confine the plasma column 210 in the radial and axial directions. In some cases, the walls or boundary of the atmospheric isolation device 203 can be reflective to the RF power, which can confine the plasma in the radial and/or axial directions. The axial confinement length 342, and the radial confinement length 343 of the plasma column 210 are shown in this example. Plasma species and activated species of the plasma column 210 can be moved in direction 344 that is approximately parallel with the axial direction 346. The plasma species can be moved through orifice 345, for example, using a pressure differential, into a downstream reaction chamber (e.g., 301 of FIG. 3A). In FIG. 3G substrate 347 can be adjacent to the orifice 345 at different distances 341 for deposition.

In some cases, the systems in FIGS. 3A-3F can be used to perform a method of forming products from one or more reactants. The method can include supplying one or more reactants to a concentration zone, wherein the concentration zone is approximately cylindrical and includes an axial direction and a radial direction (e.g., as shown in FIG. 3F). The method can further include, applying radiofrequency (RF) power to the concentration zone, where the RF power applied is sufficient to create a plasma. The method can further include, confining the plasma in the radial direction and the axial direction. For example, the RF power can be applied in an approximately cylindrically uniform manner to confine the plasma in the radial direction, and the RF power can be applied to a length of less than about half a wavelength of the applied RF power in the axial direction to confine the plasma in the axial direction. For example, the radial and axial confinement lengths 342, 343 can be those shown in FIG. 3G. The method can further include moving activated species of the plasma approximately in the axial direction through an orifice via a pressure differential into a downstream reaction chamber, expanding and cooling the activated species, and forming final or intermediate product species. For example, the systems shown in FIGS. 3A-3F can be used to perform this method, and the reactants and products can be produced using this method.

In some cases, the above method above further includes applying a Z-pinch current using a Z-pinch electrodes, as described herein. In some cases of the above method, an external Z-pinch current is not applied using Z-pinch electrodes. In some cases of the above method, a current is induced in the plasma column using the RF power (either instead of or in addition to an externally applied Z-pinch current), and electrodes are present in the system adjacent to the concentration zone and the plasma column to conduct the current through (or out of) the plasma column.

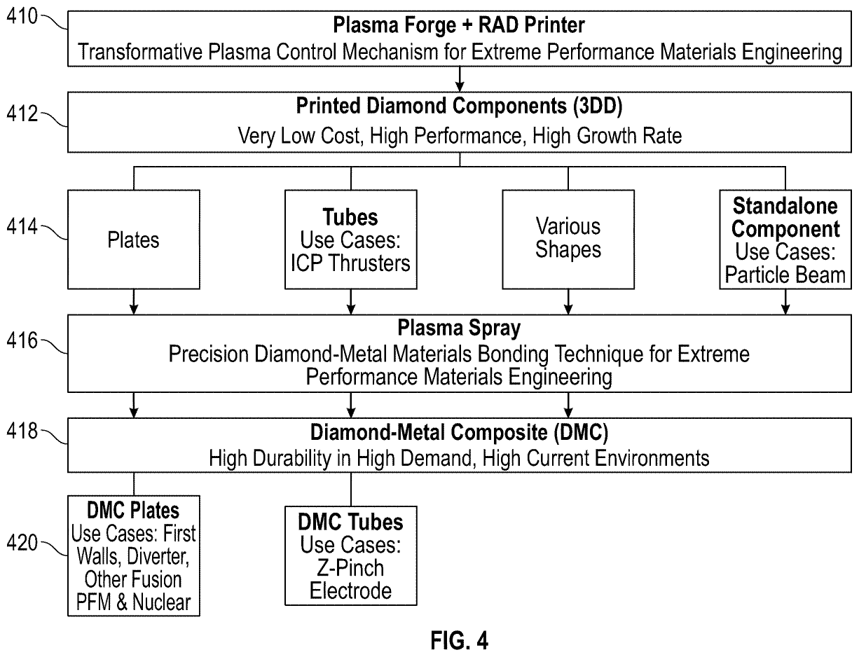

FIG. 4 shows some examples of materials and applications of the materials that can be produced using the systems and methods described herein. The systems and methods described herein can be used as a printer as suggested in box 410 and 412. For example, diamond and diamond composite structures can be produced, for example, from a methane reactant providing high performance materials at high growth rate and/or with low cost compared with traditional technologies. Example structures can include plates, tubes, complex shapes, and/or standalone components as suggested in boxes 414. As suggested in boxes 416, 418, a plasma spray can be applied which can include diamond-metal composites. Diamond-metal composite plates and tubes can be generated as suggested in boxes 420.

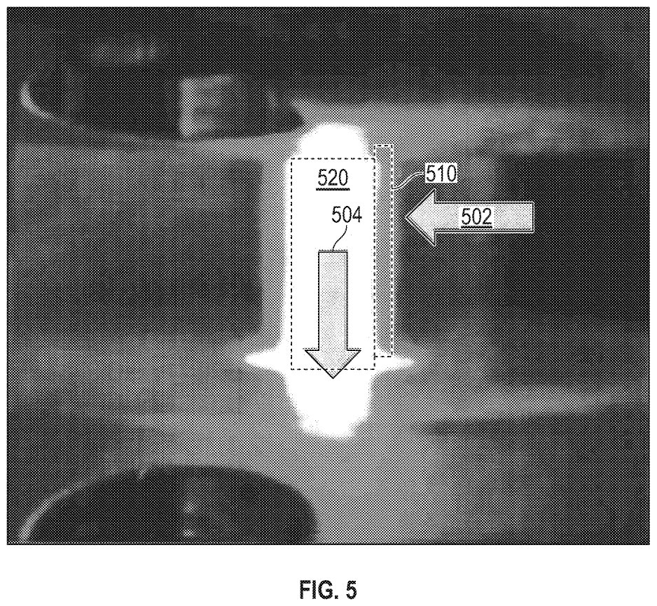

FIG. 5 shows an experimental image of a dense column of plasma (e.g., plasma column 12 in FIGS. 1B and 1C) formed using the systems and methods described herein during an hour-long test. The plasma column was a continuous duty RF driven plasma, which was free-standing and operable at vacuum or atmospheric pressure. The plasma has a power density of approximately 10 GW/m3 in some embodiments. Referring to FIG. 5, the labeled regions correspond to features of the observed plasma column and associated flow. The reference numeral 520 identifies the primary plasma column region exhibiting high intensity and density. The reference numeral 510 identifies an excitation region adjacent to the plasma column where energy coupling into the plasma is observed. The reference numeral 504 denotes a flow path or reaction trajectory along which activated species travel downstream from the plasma column. The reference numeral 502 indicates a direction of gas or species flow toward or into the plasma region. These labeled features illustrate the spatial relationship between plasma generation, excitation, and downstream transport of reactive species.

Some examples of materials, deposition techniques, and applications of the materials that can be produced using the systems and methods described herein include planar films of diamond, or diamond metal composite (DMCs) materials, or 3D structures of diamond or DMCs. The high thermal conductivity (e.g., 8×greater than state-of-the-art (SOA)) of diamond and DMCs (e.g., diamond-tungsten or diamond-copper composites) can be used in applications such as fusion reactors, advanced propulsion for spacecraft, and in high power electronics. The systems and methods described herein also enable the permanent capture of methane by converting it into the carbon-based structures described herein.

The systems and methods described herein can enable the formation of diamond in high-performance components by developing a radially additive diamond printer (RAD Printer) for 3D printing free-standing polycrystalline diamond (3DD) and diamond-metal composite (DMC) structures. The RAD Printer can enable lower manufacturing costs and rapid production of complex diamond and diamond-metal components for extreme applications like plasma-facing materials (PFMs), high-power electronics, hydrogen barriers, and thermal management. For example, DMC plates can be used in neutral particle beam systems, and large-area heat exchangers for MW-scale fusion energy systems. DMC plates can be used as fusion PFMs such as first walls and diverters, where tungsten is bonded to diamond in the DMC material. Alternatively, copper can be used as the metal, and these diamond-copper composite plates can be used in high-performance heat sinks and electronics.

In some cases, the systems and methods described herein utilize a radiofrequency-driven (RF-driven) continuous Z-pinch plasma control technology with an alternating current boost pinch. The systems and methods described herein can deliver precise plasma control and energy-efficient deposition that can grow diamond at high growth rates while achieving high quality, reducing 3DD production costs accordingly. Integrated with metal (e.g., tungsten or copper) plasma spray, this process enables DMCs that achieve high thermal conductivity while retaining electrical conductivity and high-temperature resilience. Owing to an unprecedented density for a continuous plasma column, the systems and methods described herein surpass traditional methods like plasma-enhanced chemical vapor deposition (PECVD) in volumetric growth rate and DC arc jet methods and can spatially direct growth chemistry to enable 3DD tubes and other complex structures.

Materials formed using the systems and methods described herein can be used in many different applications. Additionally, the 3DD and DMC structures can be used to permanently capture methane in sustainable carbon structures. These materials can offer enhanced resistance to erosion even at elevated temperatures, increasing the durability and efficiency of fusion reactors. For example, the materials can be used in high-power electronics, which can benefit from superior thermal management, reducing heat-induced failures. In other examples, fusion heat exchanger diamond plates, and plasma propulsion diamond tubes, can be formed.

The systems and methods described herein can include an additive diamond printer (e.g., a RAD Printer) to enable diamond and diamond composite material manufacturing and 3D printing. The RAD Printer includes a plasma formed using the systems and methods described herein, which include a plasma control mechanism originally developed for fusion energy. FIG. 3 shows a dense plasma formed using the systems and methods described herein. It achieves the plasma density and focus needed to precisely deposit diamond into complex geometries, such as tubes, which are impossible with conventional methods.

The systems and methods described herein can act as a “diamond-producing pen,” and intricate shapes can be created that address advanced thermal and structural demands across industries. FIG. 4 depicts some examples of the innovations and product possibilities that systems and methods described herein enable. The systems and methods described herein can produce CVD materials (e.g., diamond or diamond-metal composite materials) with high growth rates. Due to the energy-dense continuous plasma, diamond can be grown about 10× faster than existing methods like PECVD and DC arc jets. While PECVD can coat larger areas, it is slow and limited to simple, planar shapes. DC arc jets offer faster per-area deposition than PECVD but are limited by smaller coverage. The systems and methods described herein combine these advantages: achieving rapid deposition rates while maintaining scalability over larger areas, thanks to its dense, spatially precise plasma. By moving substrates quickly beneath the plasma deposition stream, the RAD Printer maximizes diamond throughput in both volume and quality, enabling a high throughput diamond growth platform.

As described herein, the systems and methods described herein can be used to form diamond components for many different applications such as in electronics applications and thermal management applications. With RAD Printer's unique 3D printing capability, 3D diamond (3DD) tubes can be created with thermal conductivity 1000× higher than fused silica, making them useful for applications in plasma-facing systems, high-temperature chemical reactors, and aerospace propulsion. Technologies like inductively coupled plasma (ICP) thrusters rely on electrically insulating tubes for high-performance thermal management, where 3DD enables higher power operations that existing silica or other ceramic tubes cannot withstand. RAD Printer combined with thermal spray enables the creation of diamond-metal composites (DMCs) that far exceed the performance of standard tungsten electrodes in high-current applications, such as Z-pinch fusion systems, arc welding, and industrial arc furnaces. Diamond's thermal conductivity, which is 10× greater than tungsten, reduces erosion and extends electrode life, making it a game-changer for high-demand, high-current environments. For fusion energy reactor surfaces, diamond's high thermal conductivity (10× better than tungsten) and low radiative cooling (1000× less than tungsten) make it an ideal material for managing extreme heat loads. The systems and methods described herein can produce large, thermally efficient diamond plates designed to withstand plasma interactions, opening doors to longer-lasting, higher-performing components in fusion energy applications.

The systems and methods described herein can be used in an additive process for DMC structures with high thermal conductivity, such as a 3D-diamond tube for inductive plasma equipment or for a high current electrode. The 3DD tube formed using the systems and methods described herein can have diameters of about 25 mm and a length of about 75 mm, or diameters from about 5 mm to about 100 mm, or from less than 5 mm to greater than 100 mm, and a length from about 5 mm to about 100 mm, or from less than 5 mm to greater than 100 mm. In some cases, the tubes can have a wall thickness of about 2 mm, or from 1 mm to 5 mm. In some cases, the inner diameter of the tubes can be from 20 mm to 30 mm, and the outer diameter can from 1 mm to 5 mm larger than the inner diameter. In other cases, tubes with diameter ranges of from about 1 mm to about 1000 mm could be manufactured with lengths from about 0.1 m to about 2 m, or from about 2 m to about 10 m.

The 3DD tube formed using the devices, systems, and methods described herein can be generated with a diameter within the range of about 5 mm to about 100 mm, for example, about 25 mm, and can be generated with a length within the range of about 5 mm to about 100 mm, for example, about 75 mm. Such tubes can be generated to have a wall thickness within the range of about 1 mm to about 5 mm, for example, about 2 mm. Such tubes can be generated to have an inner diameter within the range of about 20 mm to about 30 mm. diameters of about 25 mm and a length of about 75 mm, diameters from about 5 mm to about 100 mm, or from less than 5 mm to greater than 100 mm, and a length from about 5 mm to about 100 mm, or from less than 5 mm to greater than 100 mm. In some cases, the tubes can have a wall thickness of about 2 mm, or from 1 mm to 5 mm. In some cases, the inner diameter of the tubes can be from 20 mm to 30 mm, and the outer diameter can from 1 mm to 5 mm larger than the inner diameter. In some instances, tubes with diameters within the range of about 1 mm about 1000 mm can be generated with lengths within a range of about 0.1 m to about 2 m, or about 2 m to about 10 m.

Conventionally, diamond growth technology is insufficient for economical 3D printing. Additionally, it is challenging to fabricate tungsten bonded to diamond with a high thermal barrier conductance using conventional systems and methods. Diamond growth technology is currently inadequate for economical 3D printing due to limitations in growth rate, plasma density, and chemical species generation. Conventional methods, like PECVD and DC arc jet, struggle to create the high densities of atomic hydrogen and active carbon species required for rapid and high-quality diamond deposition. While DC arc jets can focus plasma more effectively than PECVD, both methods still fall short of the plasma densities and energy levels needed to sustain efficient chemistry creation at scale. This results in slow growth rates and limits diamond production to simple, flat geometries, unable to accommodate complex 3D forms. These constraints make existing diamond growth technologies prohibitively costly and restrict their application in advanced, high-tech industries that demand both intricate shapes and high-performance materials.

Bonding tungsten to diamond using conventional methods remains a significant challenge due to the difficulty of achieving a stable, high-conductivity interface between these two materials. Tungsten, prized for its high melting point and durability in extreme conditions, can be used in applications requiring high thermal resistance, such as fusion reactors. Diamond, with its exceptional thermal conductivity, could complement tungsten to form a composite material useful in many high-temperature applications. However, traditional bonding methods struggle to create a strong, conductive bond due to differences in thermal expansion and chemical incompatibilities at the interface. Without a reliable, economical process to bond tungsten and diamond with high thermal barrier conductance, the benefits of this material combination remain largely out of reach for industries requiring durable, heat-resistant components.

In some cases, the diamond and DMC tubes formed using the systems and methods described herein can be used for inductively coupled plasma (ICP) thrusters. ICP thrusters currently use quartz tubes. However, at higher power levels, quartz melts due to insufficient thermal conductivity, limiting the system's power. Alternative materials (e.g., SiO₂ and SiN) also cannot handle the same thermal loads as diamond. The systems and methods described herein (e.g., the RAD Printer) can create 3DD tubes with far superior thermal conductivity, enabling higher power levels in ICP thrusters without the risk of melting. Diamond's resilience in extreme environments will also significantly extend the lifespan of these thrusters. No currently existing method allows for the production of diamond tubes. The systems and methods described herein (e.g., the RAD Printer) provide the first technology capable of producing complex geometries like tubes and rods, opening new possibilities in propulsion and high-value applications.

In some cases, the diamond and DMC tubes formed using the systems and methods described herein can be used in Z-pinch fusion systems, which rely on high-performance electrodes capable of carrying extreme currents and withstanding significant erosion by plasma. Current electrodes made of graphite or tungsten degrade rapidly, requiring frequent replacement. The systems and methods described herein (e.g., the RAD Printer) allow the fabrication of DMC (e.g., tungsten-coated diamond) tubes for Z-pinch electrodes. Diamond's thermal conductivity, combined with tungsten's resistance to sputtering, creates a material for electrodes with improved properties that can significantly extend their operational lifespan. In addition to tungsten, DMCs (diamond metal composites) can be made using diamond and other metals such as copper, molybdenum, gold, silver, platinum, iridium, or other metallic elements and compounds.

In some embodiments, free-standing diamond plates formed using the systems and methods described herein can be used in neutral particle beam systems. Some conventional systems use silicon nitride (SiN) in neutral particle beam systems. The main limitation is that SiN's thermal conductivity and durability are insufficient for high-power operations, which limits their performance. State-of-the-art diamond components are either too expensive or cannot be shaped to the required specifications. The systems and methods described herein (e.g., RAD Printer with a rotary stage, or a similar additive manufacturing tool with a deposition substrate on an X-Y stage) enables the rapid production of large-area free-standing 3DD with custom geometries. Diamond's superior thermal conductivity and durability will allow increased power levels in neutral particle beam systems and improve heat management in MW-scale fusion heat exchangers. In contrast, traditional PECVD methods can produce diamond plates, but they are limited to flat geometries and slow growth rates (e.g., less than 40 μm/hr). The systems and methods described herein enable the production of free-standing plates in custom shapes at a faster growth rate than PECVD (e.g., 10×faster). This enables new applications that PECVD cannot serve, such as complex heat exchangers and fusion components.

In some embodiments, the diamond and DMC tubes formed using the systems and methods described herein can be used in plasma-facing materials (PFMs) in fusion reactors. Fusion reactors demand materials that withstand extreme conditions, including intense heat flux (>100 MW m-2 s0.5) and neutron bombardment, which cause rapid erosion, chemical corrosion, and thermal stress damage. The most viable current materials are tungsten and carbon-based materials (graphite, CFCs), but each has limitations. Tungsten, while durable and erosion-resistant, is prone to cracking under thermal stress. Carbon-based options, like graphite and CFCs, are limited by physical erosion, tritium retention, and chemical sputtering. The systems and methods described herein (e.g., the RAD Printer) address these challenges by enabling economical diamond-tungsten composites, which combine diamond's high thermal conductivity (up to 2200 W/m*K) and erosion resistance with tungsten's high melting point and sputtering resistance. This pairing offers a durable, customizable PFM solution with the potential to extend the lifespan of fusion components (e.g., Tokamak first walls and diverters). By achieving a diamond growth rate 10× faster than PECVD and DC Arc Jet, the systems and methods described herein enable large-area coatings, such as the 50 m² surfaces, or up to 100 m², or larger. In contrast, conventional technologies do not allow for large-scale, high-performance diamond-tungsten PFMs.

The systems and methods described herein enable the formation of carbon-based materials (e.g., diamond) more accessible, affordable, and applicable in high-performance systems. The systems and methods described herein convert a reactant (e.g., methane) feedstock into high performance diamond, and can also be used to produce versatile carbon allotropes with applicability in extreme environments. These materials enable the formation of durable plasma-facing components and high-current electrodes, for example, addressing the durability and erosion issues in fusion systems, which is critical for the economic feasibility of next-generation energy technologies.

In some embodiments, the systems and methods described herein combine the exceptional properties of two high-performance materials, diamond and tungsten, and can enable scalable, cost-effective diamond production while leveraging carbon from methane, creating a permanent capture market for carbon as a building block for future components. Some examples of the materials and components that the systems and methods described herein can form include: polycrystalline diamond coatings and structures; large structures in diamond material (e.g., meter scale structures); and diamond-metal composite (DMC) for extreme current plasma electrodes (e.g., Tokamak liners, plasma thrusters, and others).

The systems and methods described herein (e.g., the RAD Printer) includes a “print head” directing diamond or DMC growth chemistry at a workpiece. An innovative moving workpiece with closed loop control allows growth at the appropriate temperature and chemical concentration. The build platform includes materials that allow nucleation, growth, and release of 3DD. The systems and methods described herein include a high-density plasma confinement approach, which can include: a highly focused RF field creating a high energy-density continuous plasma; and high frequency pulsing of the plasma for chemistry generation and control.

In some embodiments, the systems and methods described herein form DMC structures that include bonding metal with diamond. There are several options depending on the metal. In fact, direct growth of diamond on metal is possible for molybdenum and iridium, but easily discounted based on cost, oxidation instability, or nuclear activation. However, the systems and methods described herein can include plasma thermal spray, which can work with tungsten, the material of choice for fusion energy plasma-facing applications and high temperature atmospheric applications. While bonding of tungsten has been demonstrated with spark plasma sintering, plasma spray offers easy commercialization through widespread existing use.

As mentioned previously, conventional synthetic diamond production faces three major obstacles: slow growth rates, high defect densities, and limited deposition areas. The embodiments aim to use the systems and methods described herein to overcome these hurdles delivering faster growth, lower defect densities, and larger deposition areas (through the use of a moving substrate), to enable more efficient and higher-quality diamond production.

Higher concentrations of atomic hydrogen (e.g., from 10-10 mol/cm3 to 10-7 mol/cm3) can reduce the defect density in deposited diamond layers. Increasing atomic hydrogen concentration can be achieved by raising gas temperature and density. The systems and methods described herein use focused RF energy to deliver high gas densities (e.g., about 50× greater than those in traditional microwave CVD systems), further boosted by high-frequency pulse compression. This approach overcomes previous bottlenecks in hydrogen (H) and methyl radical (CH₃) densities in state-of-the-art MWCVD/PECVD diamond synthesis.

DC Arc Plasma Jet (DCAPJ) offers an alternative approach to diamond growth. This state-of-the-art technique can achieve high temperatures and densities, surpassing MWCVD systems. However, DCAPJ can require a rotating substrate, similar to the rotating plate in household microwave ovens, and can fail to offer productivity improvement on other technologies. In contrast, the systems and methods described herein can contain a boosted microwave jet by combining the RF-Pinch and AC pulsing. Using such techniques, the systems and methods described herein can surpass the performance of DCAPJ in terms of hydrogen concentration and temperature control. The rotating substrates can be used as an additive manufacturing application head to fabricate diamond in previously unmanufacturable rotationally symmetric 3D shapes. The systems and methods described herein enable products that require the thermal conductivity of diamond combined with the conductive properties of metal. While brazing diamond to copper has been done, the systems and methods described herein can expand on the metal types possible for bonding using a plasma spray as a process for application of surface coatings on diamond substrates. With this approach, components can be formed that combine the outstanding thermal resistance and conductance of tungsten with the superlative thermal conductivity of diamond, outcompeting alternative materials.

In some embodiments, the systems and methods described herein can be used to form a high-value carbon allotrope (e.g., diamond) from methane, and in doing so, convert a fossil feedstock into a solid carbon product. In other embodiments, high-current, heat-resistant electrodes for Z-pinch fusion includes DMC tubes formed using the systems and methods described herein. These electrodes can include 3D diamond (3DD) tubes that can withstand extreme operating conditions in modular fusion reactors. They can also include DMCs formed by bonding tungsten to diamond through plasma spray. In addition to 3DD and DMC tubes, the systems and methods described herein can form other structures such as diamond or DMC rods, plates, foils, hollow shapes, vessels, and more complex shapes (e.g., with solid and hollow regions, pores, holes, and/or trusses). In some cases, any of these structures can be made from a 3DD or DMC material and include a coating of metal adhered to the structure. Multilayered structures are also possible, such as those with alternating layers of diamond and metal (e.g., tungsten or copper).

In some embodiments, the systems and methods described herein can be used to form 3DD and DMC flat plates on build platforms, where the build platforms contain molybdenum or TZM (molybdenum with less than 1% titanium, zirconium, and carbon) to provide reliable diamond nucleation and allow easy release from the substrate. The systems and methods described herein contain a plasma with a controlled density, temperature, and hydrogen concentration to achieve high growth rates and minimize sp2 contamination. In some cases, the systems and methods described herein can utilize a plasma spray process to deposit tungsten and other metals onto diamond, creating DMC structures with commercial potential. Metal coatings can be applied to diamond plates and also to diamond layers on other geometries. In some embodiments, planar build platforms can be used while in other cases cylindrical build platforms can be used. The build platforms can also be TZM rods, tubes, and foils, enabling the production of 3DD and DMC tubes. Such components (e.g., 3DD tubes) can be used in fusion applications and in other applications requiring plasma-facing components and thermal management.

The systems and methods described herein can form coarse-grain polycrystalline diamond (PCD) with properties that closely match single-crystal diamond properties when grain size and purity are optimized at fast growth rates. Other deposition methods, such as Microwave Chemical Vapor Deposition (MWCVD) and DC Arc Jet, also cannot be used to form the same materials and components as the systems and methods described herein. Traditional MWCVD can be a broad area plasma, but may not be suitable as a “print head”. DC Arc Jet can produce diamond with smaller grain sizes that may compromise the desired thermal and structural properties. The systems and methods described herein enable the growth of higher quality diamond at higher (e.g., 50×) growth rates compared to DC arc jet.

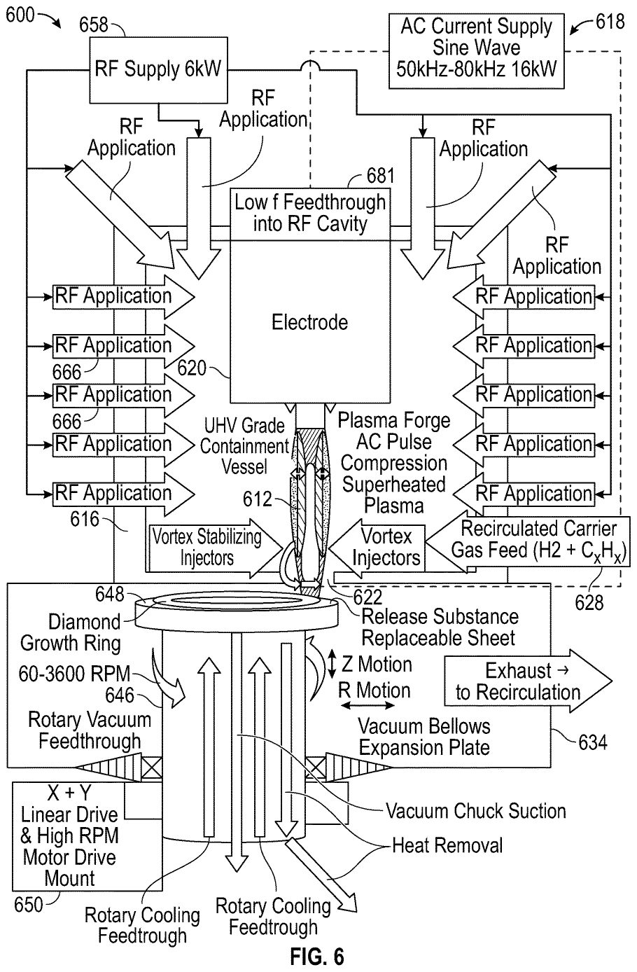

FIG. 6 shows a schematic diagram of an example of a RAD Printer system 600 that can enable the extreme plasma temperatures needed for rapid diamond growth. The system can include: a rotating stage 646 for rapid substrate 648 orientation changes, axial and radial motion using positional system 650 for precise placement relative to the plasma 612, an optional recirculating gas flow apparatus 634 for efficient gas usage, and metrology tools such as an RGA for gas purity monitoring and a pyrometer for temperature measurement. The gas inlet 628 (“Recirculated Carrier Gas Feed”) is used to form a funnel of gas with a pressure gradient at the core. The RF generator 658 (“RF Supply”) coupled to the RF Applicators 666 are used to densify and stabilize the plasma 612 at the core. The Z-pinch electrodes 620 (“electrode”) and 622 are used to apply a Z-pinch current through the plasma at the core of the funnel to further densify it using AC current supply 618. Throughout the growth process, gas recirculation rates, RPM, and temperature can be dynamically adjusted and inspected for real-time growth quality feedback. The high hydrogen densities in the systems and methods described herein can mitigate grain size shrinkage, a common limitation in DC Arc Jet processes. The system shown also includes a low frequency feedthrough 681 into the RF cavity coupled to the Z-pinch electrode 620 so that the Z-pinch current can be fed into the plasma at a lower frequency than that of the RF generator 658.

In FIG. 6, the reference numeral 612 denotes the plasma region generated within the containment vessel 616, which provides the active species for material growth. The RF Applicators 666 apply RF energy within the containment vessel 616 to sustain and densify the plasma. The reference numeral 650 denotes a drive system that provides linear and/or rotational motion to the substrate or growth platform, enabling precise positioning relative to the plasma. The reference numeral 681 denotes a low-frequency feedthrough configured to deliver electrical current to the plasma or associated electrodes at a frequency lower than the RF excitation, thereby enabling additional plasma control such as Z-pinch current modulation.

The systems and methods described herein can utilize molybdenum and TZM substrates as build platforms for both flat and cylindrical geometries. Diamond grows reliably on molybdenum and the detachment properties of TZM can enable the formation of free-standing 3DD and DMC plates, tubes, and other structures. In other cases, the build platform can be made from a different material (e.g., tungsten). The systems and methods described herein can also include plasma characterization and control in order to achieve high quality 3DD and DMC products. Plasma diagnostics can be used to monitor the plasm during operation, and can include optical emission spectroscopy (OES), pyrometry, and high-speed imaging of the plasma, as well as collisional radiative modeling. This tool suite can enable real-time adjustments to growth rate, purity, and other parameters, ensuring scalability and consistency of the materials and structures formed using the systems and methods described herein.

In some embodiments, high-purity hydrogen generators and methane can be used as the gases (or reagents, or reactants, or precursors) for diamond growth. During the growth of the 3DD or DMC, the growth parameters can be monitored and controlled. Some examples of growth parameters include gas concentration, RF power, gas recirculation rates, substrate movement (e.g., RPM), and temperature. The systems and methods described herein can use plasma spray to coat a 3DD grown layer with tungsten, creating a conductive and thermally robust surface. Plasma spray excels at creating layers of difficult-to-bond metals and ceramics and is used throughout the aerospace industry for production and repair of components.

The systems and methods described herein enable 3D printing on simple flat build plates to form 3DD and DMC structures. Additionally, the flat build plates can be replaced with cylindrical build templates. In some cases, the build plates can include active monitoring and control of motion and temperature. The temperature profile can also be varied on the workpiece in some cases. This enables forming 3DD and DMC tube products, and objects with other geometries made from 3DD and DMC materials. For example, the systems and methods described herein can be used to form a working high-current electrode design useful in a number of use cases, such as modular fusion reactors. FIG. 2 illustrates some of these structures, and applications.

In some embodiments, the systems and methods described herein enable the formation of 3DD and DMC structures with high thermal conductivity, high adhesion, and high cohesion (e.g., to a substrate, or other object). For example, a free standing diamond (3DD) thermal conductivity can be greater than 1500 W/m*K, or from 500 W/m*K to 5000 W/m*K, or higher than 5000 W/m*K at cryogenic temperature.

In some embodiments, the systems and methods described herein (e.g., systems in FIGS. 1A-1C) can include the following process parameters: plasma chamber pressure from about 20 kPa to about 150 kPa, gas flow rate from about 50 lμm to about 300 lμm, RF microwave power from about 1.5 kW to about 6 kW (or from about 1 GW/m3 to about 10 GW/m3), AC frequency from about 50 kHz to about 80 kHz, AC current from about 10 Amps to about 1000 Amps, or about 1 kA to about 10 kA, or with pulsed current delivery from 10 kA to about 1000 kA, substrate temperature from about 700 °C to about 1000 °C, dwell time under plasma from about 5% to about 100%, or from about 0.1% to 5%, and input gas methane: hydrogen ratio from about 1:1 to about 1:50, or with input gas including or exclusively methane, acetylene, or another hydrocarbon gas as input. In other cases, the RF power may range from about 6 kW to about 150 kW. In some embodiments, no AC is used. In other embodiments, DC current of 100 Amps to 10,000 amps is delivered to the Plasma.

In some embodiments, the systems and methods described herein can include the following process parameters: plasma chamber pressure from about 10 kPa to 500 kPa, an RF power of about 1 kW to 15 kW, 10 kW to 50 kW, or 30 kW to 100 KW, a metal powder feed of molybdenum, or tungsten, or other suitable metal powders at a rate of 10 g/hr to 100 g/hr, or 100 g/hr to 1000 g/hr, a gas flow rate of about 101 μm to 3001 μm of hydrogen,

In some embodiments, the systems and methods described herein can be used to form silicon carbide (SiC) materials, including polycrystalline SiC coatings, free-standing 3D silicon carbide structures, and SiC-metal composites. Silicon carbide can be deposited by introducing specific CVD precursors into the stabilized plasma system and tuning the growth parameters (e.g., plasma conditions, gas flow rates, and substrate temperature). By way of example, and not by limitation, silicon carbide films or structures can be formed by introducing a feed of metallic silicon powder and a carbon-containing gas (such as methane) into the plasma column, or by using a gaseous mixture of silane (SiH4) and methane (CH4) with a hydrogen and/or argon carrier gas. The process parameters for growing silicon carbide utilizing the RF-stabilized and/or Z-pinch plasma jet can include: a plasma chamber pressure from about 20 kPa to about 250 kPa, a gas flow rate from about 100 lμm to about 1000 lμm, an RF microwave power from about 30 kW to about 150 kW. The substrate holder may be temperature controlled via internal heat transfer fluid channels to maintain the substrate temperature within a target range suitable for high-quality SiC crystallization from about 800 °C to about 1400 °C. Utilizing the spatially precise, high-density plasma jet, the system can enable rapid, directed additive manufacturing of complex silicon carbide geometries, such as tubes and plates, useful for high-power electronics, plasma-facing materials, and extreme thermal management applications.

In further embodiments, the systems and methods described herein can be utilized for the epitaxial growth or additive deposition of wide-bandgap Group III-nitrides, such as gallium nitride (GaN), in some cases for use in high electron mobility transistors (HEMTs), optoelectronics, and advanced thermal management devices. To form GaN structures or thin films, a gallium-containing precursor such as trimethylgallium (TMG, Ga(CH₃)₃) or triethylgallium (TEG) is introduced into the stabilized plasma environment alongside a nitrogen source, such as ammonia (NH₃) or a nitrogen/hydrogen (N₂/H₂) gas mixture and the mixture is directed towards a substrate. In some embodiments, two jets are used, pointing at a single substrate, with one jet containing a gallium-containing precursor, and the other jet containing the Nitrogen source, with the substrate optionally rotated at high speeds such as 1000 RPM to 10,000 RPM, or 10,000 RPM to 100,000 RPM. The substrate is cooled or heated by heat transfer fluid in channels behind the substrate holder to maintain temperatures of −40 C to 200 C, or 200 C to 600 C, or 600 C to 800 C, or 800 C to 1100 C. The GaN growth parameters within the stabilized plasma reactor may include: a chamber pressure from about 10 kPa to about 100 kPa, a molar flow ratio of gallium source to nitrogen source ranging from 1:1 to 1:200, or 1:200 to 1:1000. Such conditions can overcome the problem of high substrate temperatures causing decomposition of some substrates, and of defect formation in GaN films.

In yet another embodiment, the systems and methods described herein can be utilized for the high-rate deposition of boron nitride (BN) solids and coatings, including both sp²-hybridized hexagonal boron nitride (h-BN) and sp³-hybridized cubic boron nitride (c-BN). To form boron nitride, a boron—containing precursor-such as boron trifluoride (BF₃), diborane (B₂H₆), or borazine (B₃N₃H₆)—is introduced into the stabilized plasma column alongside a nitrogen source, such as nitrogen gas (N₂) or ammonia (NH₃), and a hydrogen/argon carrier gas mixture. The BN growth parameters within the stabilized plasma reactor may include: a localized chamber pressure from about 10 kPa to about 500 kPa, a substrate temperature maintained between about 700 °C and 1100 °C, and the optional application of a DC substrate bias, in some cases from about −20 V to about −100 V.

In still another embodiment, the systems and methods described herein can be configured for the additive manufacturing and in-situ alloying of complex metal alloys that are highly challenging to process via traditional metallurgical methods, such as refractory high-entropy alloys (RHEAs) (e.g., W-Mo-Ta-Nb-V) and intermetallics (e.g., gamma-titanium aluminide, γ-TiAl). It should be appreciated that in some embodiments “W-Mo-Ta-Nb-V” can refer to W, Mo, Ta, Nb, V, and mixtures thereof. Deposition via stabilized dense plasma jet solves problems for deposition of such materials including vastly differing elemental melting points, extreme crucible reactivity, severe macro-segregation during cooling, and room-temperature brittleness. The present system may employ a multi-nozzle or multi-channel powder injection apparatus configured to deliver a plurality of distinct elemental or master-alloy powder feeds directly into the stabilized plasma jet. The individual mass flow rates of the multiple powder feeds can be independently and dynamically controlled via computer-actuated carrier gas streams (e.g., argon or helium) to such rates of 10 g/hr to 1000 g/hr, or 100 g/hr to 10,000 g/hr. The systems and methods described herein for deposition of multiple metallic powder feeds can include the following process parameters: plasma chamber pressure from about 20 kPa to about 500 kPa kPa, carrier gas flow rate from about 10 lμm to about 100 lμm, or 1001 μm to 1000 lμm, RF microwave power from about 1.5 kW to about 6 kW, or about 30 kW to about 150 kW, pulsed current delivery from 10 kA to about 1000kA, substrate temperature from about 100 C to about 700 C, or about 700 °C to about 1000 °C, length of plasm of about 5 mm to about 50 mm, or about 15 mm to about 150 mm, and molar input ratios of aluminum to titanium of about 1:1 to 1:3, or 1:1 to 3:1, or molar input ratios of W-Nb-Mo-Ta-V of about 1:1:1:1:1, or molar input ratios of W-Nb-Mo-Ta of about 1:1:1:1, Ti-Zr-Nb-Hf-Ta of about 1:1:1:1:1, or Al-Mo-Nb-Ta-Ti-Zr of about 2:1:2:1:2:2 or Ta-W-Mo-Ti-Zr of about 2:1:1:2:2, or other ratios of these or other metal powders. Substrate temperatures may be held to less than 660 C for aluminum containing alloys, less than 220 C for tin containing alloys, or less than 1910 C for vanadium containing alloys, or less than 1668 C for titanium containing alloys.

In various embodiments, various substrates can be used to deposit the aforementioned materials including but not limited to SiC, GaN, BN, Diamond, 3DD, Diamond composites, and complex metal alloys. For the epitaxial growth of wide-bandgap semiconductors and nitrides such as SiC and GaN, substrates may include monocrystalline silicon (Si), sapphire (Al₂O₃), silicon carbide (SiC), aluminum nitride (AlN), zinc oxide (ZnO), polycrystalline diamond, single crystalline diamond, or other materials. For the high-rate additive deposition of refractory metal alloys, cubic boron nitride, or free-standing bulk structures substrates including high-temperature refractory metals such as molybdenum, tungsten, or tantalum, high-density graphite, diamond, silicon, silicon coated with various thin films, or other composite crystalline, metallic, or ceramic materials may be utilized. Graphite substrates may optionally include a protective barrier coating, such as tantalum carbide (TaC) or pyrolytic carbon. Furthermore, for specific additive manufacturing or rapid solidification processes, the substrate may comprise an actively cooled, highly thermally conductive base such as a water-cooled copper, or aluminum, or diamond block configured to induce extreme cooling rates. Additionally, sacrificial substrates may be employed, which are subsequently removed via chemical etching or mechanical separation to yield free-standing three-dimensional structures.

The systems and methods described herein can produce 3DD and DMC structures (e.g., layers grown on flat molybdenum build plates) with high growth rates, thermal conductivity, and uniformity. The systems and methods described herein can produce 3DD and DMC structures with high elemental and phase purity and large crystal sizes. The systems and methods described herein can monitor and control the plasma temperature and density profile, which can be altered to improve the processing and properties of the resulting 3DD and DMC structures.

In some embodiments, surface prep of build plates can be done by adjusting startup parameters to achieve a lightly bonded workpiece that releases from substrate upon cooldown after growth. Some examples of startup parameters are temperature (e.g., from 500 °C to 700 °C), carbon concentration (e.g., from 1% to 50%), and startup time (e.g., from 1 min to 120 min). In some cases, the systems and methods described herein can be used to form 3DD and DMC structures with high electrical conductance, thermal barrier conductance, uniformity, and adhesion. In some cases, defects and/or tungsten carbide can form at the interfaces between the metal and diamond phases of the DMC materials.

In some embodiments, the systems and methods described herein can form 3DD and DMC structures on cylindrical substrates that are oriented at a right angle to the nozzle exit. The substrate can be mounted on a moving and rotating mount, such that it can rotate about its axis (e.g., at a high RPM) while simultaneously moving axially in an oscillatory motion to spread growth over the tube surface. In some cases, the build plate can include TZM covered (e.g., foil wrapped) substrate surfaces to assist with release of the 3DD and DMC structures from the substrate. In some embodiments, the 3DD and DMC structures described herein can be integrated into systems to provide a material with suitable properties, such as thermo-mechanical, electrical, magnetic, heat, and fluid management properties required for passing high current and efficiently extracting heat from a component (e.g., a plasma facing component in a Z-pinch fusion reactor). In some embodiments, the systems and methods described herein can be used to form a Z-pinch electrode including a metalized diamond tube.

In some embodiments, the systems and methods described herein can include plasma control mechanisms that enable a dense and high temperature plasma to be formed in a space. The generated plasma can be used to form diamond, for example, using methane as a process gas, and the stream of reactants can be output (e.g., from a nozzle) and deposit upon a substrate outside the space. The substrate can be rotated and/or moved laterally with respect to the out stream and the system can operate as a 3D printer. The dense plasma can be formed using RF microwave stabilization fields in addition to a pulsed Z-Pinch current to further confine the plasma. Alternating current can be used to further compress the plasma column and pulse the concentration of various species in the plasma. The reactant gas, in some cases, can also flow through the electrode structure. In some cases, the reactant gas can be recirculated into the space.

In some embodiments, the systems and methods described herein can include plasma control mechanisms including tuning the alternating current to optimize the plasma environment for alternating chemical reactions during diamond growth, leading to faster and more efficient production. The systems and methods described herein can enable 3DD printing, for example, complex shapes such as tubes and hybrid structures with precise control over geometry and material properties.

FIGS. 7-10 describe an integrated additive manufacturing platform in which a stabilized plasma jet is precisely controlled relative to a substrate to enable directed, high-temperature deposition of materials, including CVD, PVD, and plasma-sprayed species. These figures collectively expand the disclosure from a static deposition concept to a fully dynamic, multi-axis growth system capable of producing complex geometries and composite structures.

FIG. 7 illustrates a material growth stage assembly configured for radial or otherwise directed additive deposition. A substrate 704 is mounted on a substrate holder 706 that secures the substrate via vacuum suction, mechanical retention, adhesion, or semi-permanent bonding such as brazing or deposited interface layers. The substrate holder 706 is thermally engineered, for example using high-conductivity materials or thermally resistant structures, to maintain substrate temperatures across a wide range depending on the deposition process in some embodiments. The holder 706 is mounted on a rotating shaft 708 supported by bearings in some embodiments and coupled through a rotary feedthrough 710 that enables both mechanical rotation and fluid transfer. The feedthrough allows delivery of cooling fluids 714 and vacuum suction 716 to the substrate holder 706 during operation. A motor 717 drives rotation of the shaft, with speed control coordinated by a controller 718 to match deposition conditions. The entire rotating assembly is enclosed within an environmental containment region 712, which may be vacuum or controlled atmosphere, and is separated from external components by a flexible environmental separator 722 such as a bellows, membrane, or ferrofluidic seal in some embodiments. The stage 720 is mounted on a translation platform capable of motion in multiple axes, allowing precise positioning of the substrate relative to the plasma deposition jet. The plasma jet 700 impinges on the substrate 704, depositing activated species that form a material layer 702, with deposition governed by plasma chemistry, particle flux, and substrate conditions. A plasma jet 700 refers to a flow of plasma and/or plasma-derived species that is directed along a defined trajectory from a plasma generation region toward a target region. Plasma jet 700 can be created using any of the systems described herein, e.g., those in FIGS. 1A-3G. The plasma jet 700 may include ionized species, neutral species, radicals, and/or particulates, and may be formed by pressure gradients, gas flow, electromagnetic forces, or nozzle geometries such as venturi structures. The plasma jet 700 may be continuous or pulsed and may be configured to transport energy and reactive species to a substrate for deposition, modification, or chemical reaction.

In some embodiments, the plasma jet defines a deposition footprint on the substrate having a characteristic width or diameter. The size and shape of the deposition footprint may be controlled by one or more parameters including nozzle geometry, plasma confinement, RF power, gas flow rate, pressure, or distance between the plasma outlet and the substrate. Control of the deposition footprint enables adjustment of spatial resolution, layer thickness, and feature size in the resulting structure. In FIG. 7, elements 704-718 correspond to the substrate, holder, shaft, feedthrough, motor, and controller described above.

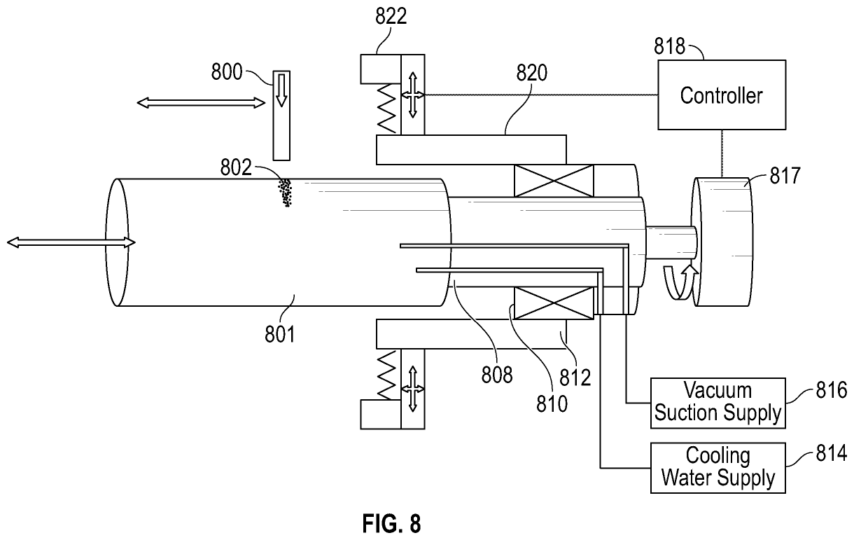

FIG. 8 builds on the architecture of FIG. 7 by emphasizing the interaction between the stabilized plasma jet and a rotating substrate oriented at a controlled angle relative to the jet axis. It should be appreciated that the architecture for the system of FIG. 8 illustrates a material growth stage assembly in which a stabilized plasma deposition jet 800 is directed toward a rotating substrate or release material 801 arranged at a controlled orientation relative to the jet axis. The system may include a substrate secured to a substrate holder, which may retain the substrate using vacuum suction 816, mechanical clamping, adhesive bonding, or a semi-permanent interface layer such as a deposited or brazed film. In some embodiments, the substrate further comprises a release layer 801 or coating to facilitate separation of the deposited material after growth and thus the release material 801 functions as a substrate and substrate holder in some embodiments. The substrate holder/release material 801 is mounted to a shaft 808, which is supported by rotary bearings and extends through a rotary feedthrough 810 in some embodiments. The rotary feedthrough 810 is configured to transmit both mechanical rotation and fluid connections, including a cooling fluid supply 814 line and a vacuum suction 816 line coupled to the substrate holder for thermal management and substrate retention. The shaft 808 is mechanically coupled to a drive motor 817, such as a brushless DC motor or AC motor, which provides controlled rotational motion of the substrate about its axis, with rotational speed governed by a controller 818. The rotating assembly is enclosed within an environmental containment region, which may be maintained at vacuum or controlled pressure, and is isolated from external components by a flexible environmental separator 822, such as a bellows, membrane, or ferrofluidic seal, that accommodates motion while preserving the controlled environment in some embodiments.

The substrate holder and rotating assembly are further coupled to a translation stage that provides motion in one or more linear axes, such as X, Y, and Z directions, enabling positioning of the substrate relative to the plasma deposition jet 800. The translation stage may include linear actuators, motors, or manual adjustment mechanisms, and may be integrated with a sealed translation apparatus to maintain environmental integrity during motion. The stabilized plasma generation device produces a plasma deposition jet 800 that is directed toward the substrate at a defined angle relative to the substrate axis. In some embodiments, the axis of the plasma generation device (or associated plasma chamber and outlet) is oriented approximately perpendicular (e.g., about 90 degrees offset) relative to the rotational axis of the substrate holder, such that the plasma jet impinges laterally onto a rotating cylindrical or otherwise elongated substrate surface. This perpendicular orientation enables radial deposition about the circumference of the substrate as it rotates, thereby facilitating formation of tubes, cylindrical shells, and other rotationally symmetric or circumferentially built geometries. In some cases, the perpendicular orientation also enables controlled buildup of non-axisymmetric or contoured geometries by coordinated rotation and translation of the substrate relative to the plasma jet.

During operation, controller 818 coordinates rotation of the substrate, translation of the stage 820, and plasma operating parameters so that the plasma jet 800 can be swept across the substrate surface to deposit material via chemical vapor deposition, physical vapor deposition, plasma spray, or combinations thereof. The angular relationship between the plasma jet axis and the substrate axis may be fixed or dynamically adjustable, allowing control over deposition directionality, coating uniformity, and growth morphology. This coordinated motion enables uniform coverage, patterned deposition, or buildup of free-standing structures, with the release layer optionally allowing the completed structure to be removed from the substrate after processing. In alternative embodiments, the relative orientation between the plasma generation device (or associated plasma chamber and outlet) and the substrate holder is not limited to a perpendicular arrangement and may include any fixed or variable angle between about 0 degrees and about 180 degrees. For example, the plasma jet 800 may be oriented at an oblique angle (e.g., about 15°, 30°, 45°, 60°, or) 75° relative to the substrate rotational axis or may be dynamically adjustable during operation using one or more articulating mounts, gimbals, or multi-axis positioning systems. In some cases, the plasma jet may be substantially parallel to the substrate axis to enable axial deposition along elongated structures, while in other cases the jet angle may be varied during deposition to control local growth direction, layer thickness, or microstructure. This variable angular orientation enables formation of a wide range of geometries, including tapered structures, non-uniform thickness profiles, contoured surfaces, lattice or graded structures, and hybrid geometries combining axial and radial buildup. The controller 818 may be configured to dynamically adjust the angle between the plasma jet 800 and the substrate in coordination with substrate rotation, translation, and plasma operating parameters to achieve desired deposition characteristics and complex three-dimensional shapes.

In some embodiments, the plasma jet 800 may be operated in a continuous deposition mode or in a discrete deposition mode. Continuous deposition may include sweeping or scanning the plasma jet 800 relative to the substrate to form continuous tracks or layers, while discrete deposition may include pulsed operation or localized bursts of material delivery to form segmented or voxel-like features. The system may be configured to follow a predefined or dynamically generated toolpath, enabling patterned deposition, rastering, or point-by-point material placement. In FIG. 8, elements 801, 808, 810, 814, 816, 817, 818, 820, and 822 correspond to the substrate or release material, shaft, feedthrough, cooling supply, vacuum supply, motor, controller, translation stage, and environmental separator described above.

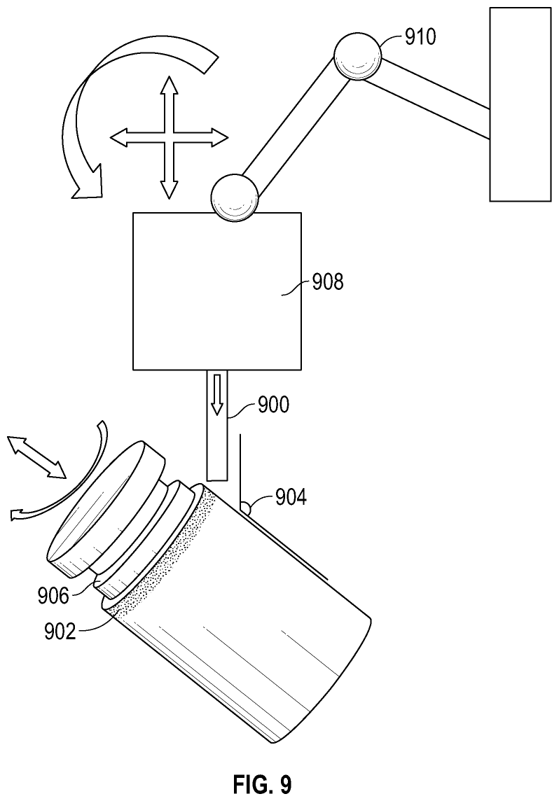

FIG. 9 illustrates a deposition configuration in which a stabilized plasma generation device is mounted on a multi-axis articulating arm 910 and directed toward a substrate supported on a contoured substrate holder 906, enabling conformal coating and additive buildup on non-planar geometries. The system includes a stabilized plasma generation device 908 configured to produce a plasma deposition jet 900, wherein the device may include a plasma chamber, one or more RF or other energy sources, and an outlet or nozzle through which activated species are expelled to form the deposition jet 900. The plasma generation device 908 is mechanically coupled to a multi-axis articulating arm 910, which may include a series of linked segments connected by rotational joints, pivots, or gimbals, each joint being actuated by motors or other drive mechanisms to provide multiple degrees of freedom. The articulating arm 910 is configured to position and orient the plasma generation device 908 in three-dimensional space, including translation and rotation about one or more axes, thereby enabling adjustment of the direction, angle, and distance of the plasma deposition jet relative to the substrate in some embodiments. In other embodiments, the articulating arm 910 is further coupled to a base or support structure and may include integrated routing for electrical power, gas delivery lines, cooling lines, and control signals to the plasma generation device. In FIG. 9, plasma deposition jet 900 is generated by plasma generation device 908 and directed toward a substrate supported on contoured substrate holder 906. The plasma generation device 908 is mounted on articulating arm 910, and angle 904 defines the orientation between the jet and the substrate surface. Deposited material 902 forms on the substrate as a result of the directed plasma.

The substrate is supported on a contoured substrate holder 906, which may include a shaped or profiled surface configured to match or approximate the geometry of the desired deposited structure. The substrate holder 906 is coupled to a rotational stage, allowing the substrate to rotate about an axis, and may further be coupled to a translation stage providing motion in one or more linear directions. The rotation and translation stages may be driven by one or more motors under control of a controller, enabling coordinated motion of the substrate relative to the plasma jet. The angle 904 between the plasma deposition jet 900 and the local surface of the substrate is defined by the orientation of the articulating arm and may be adjusted to maintain a desired incidence angle relative to the surface normal, thereby enabling uniform deposition 902 across curved or irregular surfaces. In some cases, the angle 904 between the substrate axis and the plasma deposition axis is varied dynamically during operation to achieve controlled coating thickness, adhesion, and microstructure across different regions of the substrate.

During operation, the controller coordinates movement of the articulating arm 910, rotation of the substrate holder 906, and any translational motion of the substrate to direct the plasma deposition jet 900 across the contoured substrate surface in a controlled path. This coordinated multi-axis motion enables conformal coating, localized deposition, or additive buildup of material using chemical vapor deposition, physical vapor deposition, plasma spray, or combinations thereof for the depositing of material 902. The system thereby supports fabrication of complex geometries, including curved surfaces, non-axisymmetric shapes, and structures with spatially varying thickness or composition, by controlling the relative positioning and orientation of the plasma source and the substrate throughout the deposition process.

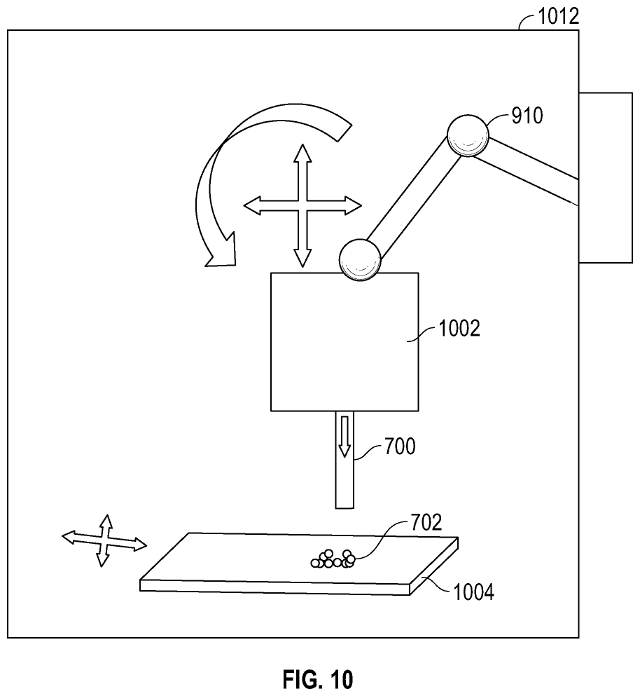

FIG. 10 further generalizes the system into a full additive manufacturing platform in which both the plasma source and the substrate platform can move in multiple axes. The stabilized plasma generation device 1002 remains mounted on an articulating arm 910, while the substrate or build plate is mounted on a multi-axis translating base 1004 within an environmentally isolated region 1012. This configuration allows coordinated motion between the deposition source (plasma jet 700) and the build surface, enabling layer-by-layer fabrication of free-standing structures. The system can deposit materials 702 in discrete regions or continuously across the substrate and can switch between different material inputs or deposition modes to form multi-material or composite structures. The ability to control deposition position, orientation, and sequencing enables fabrication of complex three-dimensional components with spatially varying composition and structure, using combinations of chemical vapor deposition, physical deposition, and thermal or plasma spray techniques. In some embodiments, material is deposited in a layer-by-layer manner, region-by-region, or continuously to form free-standing structures. Successive layers may be deposited with controlled thickness and composition to build three-dimensional objects. The system may also be configured to vary deposition parameters between layers or within a layer to produce graded materials, composite structures, or regions with differing physical or chemical properties. In FIG. 10, plasma generation device 1002 produces plasma jet 700, which deposits material 702 onto a substrate supported by multi-axis translating base 1004 within environmental isolation region 1012. The articulating arm 910 and translating base 1004 enable coordinated motion for additive manufacturing.

In some embodiments, the controller is configured to switch between different reactants, plasma conditions, or deposition modes during operation to produce multi-material or compositionally graded structures. The switching may occur between layers, within a layer, or at discrete regions of the substrate, enabling fabrication of structures with spatially varying composition or functional properties.

Taken together, FIGS. 7-10 describe a progression from a controlled rotating substrate system to a fully articulated, multi-axis additive manufacturing platform in which both the plasma jet and the substrate can be dynamically positioned concurrently or separately. This enables precise spatial control of high-energy deposition processes, supports a wide range of materials and deposition mechanisms, and allows fabrication of complex geometries including free-standing, layered, and composite structures with tailored properties. It should be appreciated that the embodiments enable localized deposition, which refers to deposition of material onto a substrate within a confined spatial region that is smaller than the overall substrate area, such that material growth is spatially controlled and restricted to a defined footprint. Localized deposition may be achieved by directing a plasma, plasma jet, or activated species stream to a specific region of the substrate, optionally in combination with relative motion between the deposition source and the substrate to selectively build material in desired locations. In addition, the embodiments provide for directed growth which refers to controlled formation of material on a substrate in which the position, orientation, and/or geometry of the deposited material is determined by one or more controllable parameters. Such parameters may include positioning of a plasma source, movement of a substrate, modulation of plasma conditions, or controlled delivery of reactants. Directed growth may include additive manufacturing processes in which material is deposited sequentially in predefined patterns, paths, or layers to form structures with designed geometries.

In some embodiments, the system operates as an additive manufacturing system in which the plasma jet functions as a controllable print head and the substrate and/or plasma source is moved relative to one another according to a programmed toolpath. A controller coordinates plasma generation, reactant delivery, and relative motion between the plasma jet and the substrate, optionally in a closed-loop manner using sensor feedback, to control deposition rate, spatial location, material composition, and geometry of the deposited structure. This coordinated control enables fabrication of complex three-dimensional components with high spatial precision and tailored material properties.

In contrast to conventional plasma spray or chemical vapor deposition systems that typically deposit material over broad or uncontrolled regions, the systems described herein provide a spatially confined deposition region. The confinement and directionality of the plasma jet enable selective material growth at defined locations on the substrate, thereby supporting patterned deposition and additive manufacturing processes with improved precision and reduced material waste.

The plasma utilized in the systems described herein, including those associated with FIGS. 7-10, may be generated using one or more plasma generation techniques, wherein each technique includes one or more components configured to couple energy into a gas to form and sustain a plasma comprising active species for material deposition.

In some embodiments, the system comprises one or more radiofrequency (RF) generators, one or more RF applicators, and one or more RF distributors configured to deliver RF energy to a gas within an atmospheric isolation device or plasma generation region. The RF energy may be coupled into the gas via one or more resonant cavities, waveguides, inductive coils, capacitive electrodes, or combinations thereof, thereby ionizing the gas and forming a plasma. The RF energy may be applied continuously or in a pulsed manner and may be configured to pre-ionize the gas, sustain the plasma, and/or stabilize a plasma column. In some embodiments, the RF energy alone is sufficient to generate and maintain the plasma without the application of an external current or a direct current.

In some embodiments, the system comprises one or more electrodes, including one or more cathodes and one or more anodes, and one or more power supplies configured to apply a voltage and/or current between the electrodes. The applied electric field may accelerate charged particles to ionize a gas and form a plasma. The one or more power supplies may include direct current (DC), pulsed DC, alternating current (AC), or combinations thereof. In some embodiments, the system is configured to drive a current through the plasma sufficient to generate magnetic forces that compress the plasma, including via a Z-pinch effect, thereby increasing plasma density and temperature.

In some embodiments, the system comprises a Z-pinch drive device configured to drive current through a plasma column to produce a Lorentz force that radially compresses the plasma column. The Z-pinch may be driven using DC current, pulsed current, alternating current, or RF-induced current. In some embodiments, the Z-pinch is used to increase plasma density, temperature, and confinement, thereby enhancing reaction rates and deposition efficiency. In some embodiments, the system comprises a combination of RF energy delivery and electrode-driven current, wherein one or more RF generators are configured to pre-ionize and/or stabilize the plasma, and one or more power supplies are configured to drive current through the plasma to generate a Z-pinch. The RF energy and the current may be applied simultaneously, sequentially, or in a coordinated manner by a controller, thereby enabling independent control of plasma density, temperature, stability, and confinement.

In some embodiments, the one or more RF generators are configured to operate in a microwave frequency range, and the system comprises one or more microwave applicators configured to generate a high-density plasma within a cavity or waveguide structure. The microwave energy may be configured to produce a plasma with reduced electrode interaction and high concentrations of reactive species. In some embodiments, the system comprises one or more inductive coils configured to generate time-varying magnetic fields that induce currents within a gas to form an inductively coupled plasma (ICP). The ICP may be generated without direct electrical contact between electrodes and the plasma, thereby reducing contamination and enabling formation of a substantially uniform plasma.

In some embodiments, the system comprises one or more capacitively coupled electrodes configured to generate an oscillating electric field that ionizes the gas to form a capacitively coupled plasma (CCP). The CCP configuration may be used to control ion energy at a substrate and influence deposition characteristics. In some embodiments, the system comprises one or more arc-generating electrodes configured to produce a plasma via an electrical arc. The arc-generated plasma may be expelled through one or more nozzles to form a plasma jet having high temperature and high enthalpy suitable for thermal spray or high-energy deposition processes. In some embodiments, the system comprises a remote plasma source configured to generate a plasma in a region separate from a deposition region, and one or more conduits, pressure gradients, or flow paths configured to transport the plasma into the deposition region. The remote plasma source may be used to decouple plasma generation conditions from substrate conditions.

In some embodiments, the system comprises one or more laser sources configured to generate a plasma by ionizing a gas or ablating a material, thereby forming a laser-induced plasma plume. The laser-induced plasma may be generated in a pulsed manner and may be used to initiate or supplement plasma formation. In some embodiments, the system further comprises one or more gas injectors, nozzles, or flow control elements configured to direct a gas flow, a plasma, or active species along one or more flow paths. The gas flow may include one or more of radial, axial, or tangential components, and may form a vortex flow, shear flow, or pressure gradient configured to shape and confine the plasma. In some embodiments, one or more venturi nozzles or orifices are configured to accelerate and direct the plasma into a plasma jet.

In some embodiments, the system comprises a controller operatively coupled to the one or more RF generators, power supplies, electrodes, Z-pinch drive device, and/or gas delivery components, wherein the controller is configured to coordinate operation of the plasma generation system. The controller may be configured to adjust one or more parameters including frequency, power, current, voltage, gas flow rate, pressure, or timing to control plasma formation, stability, confinement, and composition. In some embodiments, the plasma is generated using one or more of the foregoing techniques in combination, such that a first plasma generation mechanism establishes a baseline plasma and a second plasma generation mechanism modifies one or more plasma properties. For example, RF energy may be used to sustain a plasma while a Z-pinch current increases plasma density, or an inductively coupled plasma may be further energized by RF or arc-based heating near a nozzle. The details of the plasma chamber are further described with respect to application Ser. No. 19/297,550 and application Ser. No. 63/903,721, both of which are incorporated by reference for all purposes.

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof. While particular combinations of various functions and features of the one or more embodiments are expressly described herein, other combinations of these features and functions are likewise possible. The present disclosure is not limited by the particular examples disclosed herein and expressly incorporates these other combinations.

Embodiments of the disclosed invention have been referenced in detail, and one or more examples of the disclosed invention have also been illustrated in the accompanying figures. Each of the embodiments and examples herein have been provided to explain the present technology, not as limitations of the present technology. Furthermore, while particular embodiments of the invention have been described in detail, it will be appreciated that alterations to, variations of, and equivalents to these embodiments may be readily conceived of by those skilled in the art, upon attaining an understanding of the foregoing. For instance, features illustrated or described with respect to one embodiment may be used with another embodiment to yield an additional embodiment. It is intended that the present subject matter covers all such modifications and variations within the scope of the appended claims and their equivalents. Those of ordinary skill in the art may practice these and other modifications and variations to the present invention without departing from the scope of the present invention, which is more particularly set forth in the appended claims. Furthermore, the foregoing description is by way of example only, and is not intended to limit the invention, as will be appreciated by those of ordinary skill in the art.

What is claimed is:

1. A system, comprising:
a plasma chamber and one or more energy sources configured to generate a plasma, wherein a stabilized plasma formed in the plasma chamber is densified using an RF field generated by at least one of the one or more energy sources, and a magnetic confinement force generated by current within the plasma;
a reactant inlet into the plasma chamber, wherein one or more reactant species are converted into active species in the stabilized plasma;
an outlet from the plasma chamber, through which the active species leave the plasma chamber; and
a substrate support configured to support a substrate positioned adjacent to the outlet such that the active species form a material on the substrate.

2. The system of claim 1, wherein the substrate support is one of a moving or rotating mount such that plates, tubes, or other structures can be formed on the substrate.

3. The system of claim 1, wherein the substrate is a rotatable cylinder.

4. The system of claim 1, wherein the material comprises diamond.

5. The system of claim 1, wherein the one or more reactant species includes methane.

6. The system of claim 1, wherein the one or more reactant species includes a metal, and wherein the material on the substrate comprises a composite material of diamond and the metal.

7. The system of claim 6, wherein the composite material comprises one of diamond and tungsten or diamond and copper.

8. The system of claim 1, wherein the material comprises one of an oxide or a nitride.

9. The system of claim 1, wherein the one or more reactant species includes a metal, and wherein the material on the substrate comprises a composite material of the metal and one of an oxide or a nitride.

10. A method for materials deposition, comprising:
forming a stabilized plasma in a plasma chamber;
densifying the plasma using an RF field generated by an RF generator;
further densifying the plasma using a magnetic confinement force generated by current within the plasma;
introducing one or more reactants into the stabilized plasma using a reactant inlet into the plasma chamber;
converting the one or more reactants into active species in the plasma;
outputting the active species through an outlet from the plasma chamber; and
forming a material on a substrate.

11. The method of claim 10, wherein the substrate is mounted to a one of a moving or rotating mount such that plates, tubes, or other structures are formed on the substrate.

12. The method of claim 10, wherein the substrate is a rotatable cylinder.

13. The method of claim 10, wherein the material comprises diamond.

14. The method of claim 10, wherein the one or more reactants include methane.

15. The method of claim 10, wherein the one or more reactants include a metal, and wherein the material on the substrate comprises a composite of diamond and the metal.

16. The method of claim 10, wherein the material comprises one of an oxide or a nitride.

17. The method of claim 10, wherein the one or more reactants include a metal, and wherein the material on the substrate comprises a composite material of the metal and one of an oxide or a nitride.

18. A method for additive deposition, comprising:
forming a stabilized plasma column in an isolation container from at least one first reactant;
applying electrical current through an interior of the isolation container to pass through the stabilized plasma column to produce a magnetic confinement force generated by current within the plasma;
flowing at least one second reactant into the isolation container for conversion into active species of the stabilized plasma column; and
outputting at least a portion of the active species of the stabilized plasma column as deposition material onto a substrate.

19. The method for additive deposition of claim 18, further comprising applying RF to the plasma column.

20. The method for additive deposition of claim 18, wherein the at least one first reactant includes methane and at least a portion of the deposition material comprises diamond.

21. The method for additive deposition of claim 18, wherein the at least one second reactant includes a metal and at least a portion of the deposition material comprises a diamond-metal composite.

22. The method for additive deposition of claim 18, wherein at least a portion of the deposition material comprises one of an oxide or a nitride.

23. The method for additive deposition of claim 18, further comprising moving the substrate to support additive deposition of the deposition material onto the substrate.

24. The method for additive deposition of claim 18, wherein the stabilized plasma is generated by a Z-pinch plasma system.
